(19) United States
(12) Patent Application Publication
(10) Pub. No.: US 2008/0079483 A1
(43) Pub. Date: Apr. 3, 2008

(54) Circuit and device for processing digital data

(76) Inventor: Shoich Ono, Tokorozawa (JP)

Correspondence Address: Shoich Ono, Hongou 1105-1-419, Tokorozawa, 359-0022, JP

(21) Appl. No.: 11/710,104

(22) Filed: Feb. 26, 2007

(30) Foreign Application Priority Data
Feb. 28, 2006 (JP) 2006-053471

(51) Int. Cl. G06F 17/10; G06K 9/40; H03K 5/00

(52) U.S. Cl. 327/551; 382/260; 708/304

(57) ABSTRACT

A digital comparator includes a plurality of bit comparators. Each bit comparator generates a matching signal when the values between a first 1 bit data and a second 1 bit data are equal, while a mismatch signal when the values between the first 1 bit data and the second 1 bit data are unequal; receives a matching signal or a mismatch signal transmitted from an upper bit comparator or a fixed signal generated by an electronics component; transmits a mismatch signal to a lower bit comparator when generating the mismatch signal or the receiving the mismatch signal, while a matching signal to the lower bit comparator when generating the matching signal and receiving the matching signal or the fixed signal; and outputs the first 1 bit data being input to the input circuit when generating the mismatch signal and receiving the matching signal or the fixed signal.

### CROSS-REFERENCE TO RELATED APPLICATIONS

This application claims the priority benefit from 35 U.S.C. Section 119 on the basis of Japanese Patent Application No. 2006-053471, filed on Feb. 28, 2006, whose title is “CIRCUIT FOR COMPARING AND PROCESSING DATA, INTEGRATE CIRCUIT AND IMAGE PROCESSING APPARATUS”, the entirety of which is incorporated herein by reference.

### BACKGROUND OF THE INVENTION

1. Field of the Invention

The present invention relates to a circuit and a device for processing digital data and, in particular, to a median filter and a digital comparator for processing digital data. The present invention further relates to an integrate circuit incorporating the data processing circuit, and to an image processing apparatus including the integrate circuit.

2. Description of Related Art

Today, computer systems becoming widespread, a data processing circuit for comparing two digital signals often processes data concerning several kind of information, after converting analog signals into digital signals. For example, a system, such as measuring equipment controlled by a computer, converts measured value as analog signal obtained from a temperature or force sensor into digital signal and processes it. An alternative system converts analog signal of image photographed by a video camera or the like or of audio data such as music into digital signal and processes it. A data processing circuit for comparing data may take a number of forms, for example, including not only a simple comparator circuit but also a CPU (Central Processing Unit) and a memory circuit storing programs and data for supporting to process data.

Recently, processing speed of CPUs and storage capacity of a memory circuits have been increased by leaps and bounds. For example, the processing speed of the CPUs in 2006 becomes faster about 1,000 times that of the CPUs in the past several tens of years. In the past several tens of years, since processing speed of peripheral data processing circuits are faster than that of CPUs, and storage capacity of the memory circuits are small, the peripheral circuit must wait until processing of the CPU is finished. Today, in contrast to this, since the processing speed of the CPUs has been dramatically increased; the CPU must wait until the processing of the peripheral circuit is finished. One of the reasons of this, CPUs are high-priced devices, so that they will become highly profitable products even though spending the resources such as facilities and manpower. In contrast to this, peripheral circuits for data processing are low-priced devices and many makers can product them, so that they will not become highly profitable products in spite of spending the resources. However, unless increasing the processing speed of the peripheral circuits, the bottleneck in data processing of the system can not be solved for a long time to come due to the mismatch between the CPUs and peripheral circuits. In particular, today, the memory circuits storing large amount of data such as image or audio are significantly increased, it is strongly desired to increase the data processing speed in the system.

When the image photographed by the video camera or the like is converted from the analog signal into the digital, then it is stored in an image memory circuit such as a frame memory which can store the image data as two-dimensional pixel data of one or more frames. It is known that some methods reduce noise included in the two-dimensional pixel data. One method for reducing noise is a moving-average method. In the moving-average method, for example, nine pixels data consisting of specific one pixel data and adjacent eight pixels data that are positioned at right and left, upper and below, and four slanting directions of the specific pixel data are read out. Then, the value of the specific pixel data is replaced with the average value of the nine pixels data. However, there is a problem that the resolution of the specific pixel data becomes degradation, because the edge that forms the outline of the specific pixel data is reduced as well as the noise.

Today, for this reason, a new noise reduction method of median filter process that replaces a value of a target pixel for noise reduction with a median value among nine pixels including the target pixel has been adopted.

For example, an approach in this direction has been achieved in: Tomoyuki Hamamura, and Bunpei Irie, “A fast Algorithm for 3 times 3 Median Filtering”, FIT (Forum on Information Technology) Letters, vol. 1, No. 1, pp 141-142 (Sep. 13, 2002), which is disclosed in Japanese Patent Application No. 2003-3435 (Laid-open; Aug. 5, 2004), where nine pixel data are divided into three groups A, B, and C, each having three pixel data. The three pixel data of each group are sorted in descending order. Then, an algorithm that compares the middle value of B and minimum value of A, and the middle value of B and maximum value of C, in order to reduce the average number of the comparison.

Another approach is disclosed in Japanese Patent Application No. 1996 (Heisei 8)-8090 (Laid-open; Jul. 31, 1997), titled “METHOD AND APPARATUS FOR PROCESSING OF VIDEO SIGNAL”. In this publication, a first median filter operator 21 has a comparator 19 and a median value decision section 20. The comparator 19 compares a specified pixel signal and two pixel signals horizontally adjacent to the specified pixel read out from a first memory 11. The median value decision section 20 selects a median value based on the comparison of the comparator 19. The first median filter operator 21 stores the median value as the value of the specified pixel signal into a second memory 22. A second median filter operator 25 has a comparator 23 and a median value decision section 24. The comparator 23 compares a specified pixel signal and two pixel signals vertically adjacent to the specified pixel read out from a second memory 22. The median value decision section 24 selects a median value based on the comparison of the comparator 23. The second median filter operator 25 stores the median value as the value of the specified pixel signal into a third memory 26. (cf. FIG. 4 thereof)

Another approach is disclosed in Japanese Patent No. 3,439,306 of Hirosh Nagata and al. (Laid-open No. Heisei 10-84498; Mar. 31, 1998), titled “NOISE REDUCTION CIRCUIT AND APPARATUS FOR PROCESSING OF IMAGE SIGNAL”. This patent discloses a noise reduction circuit for reducing noise with addition-subtraction operation of DC components corresponding magnitude of noise in input image signal, comprising: means for detecting edge portion of the in input image signal; means for generating DC components in response to the detected noise; means such as a median filter for generating a first reference signal that closes to a signal without noise in the edge portion of the in input image signal; means for generating a second reference signal that closes to a signal without noise in about flat portion except the edge portion; means for selecting the first or second reference signal in response to the detecting result of the edge detecting means; and means for comparing the levels of the selected reference signal and input image signal, and for performing, in response to the comparing result, addition-subtraction operation of the DC components on the input image signal.

Another approach is disclosed in Japanese Patent No. 3,463,640 of Masariro Yadokoro (Laid-open No. 2001-197333; Jul. 19, 2001), titled “DIGITAL NOISE REDUCTION CIRCUIT”. This patent discloses that when selecting median value by using a median filter, a parallel comparison processing on two pixels is performed without time series processing such as sort processing.

Another approach is disclosed in Japanese Patent Application No. 1991 (Heisei 3)-154751 (Laid-Open; Jan. 8, 1993), titled “METHOD FOR SEQUENCE FILTERING”. This discloses that after nine data that consist of 3 times 3 are read out and sorted them in decreasing order of magnitude, selecting candidate data step-by-step in order to detect the target data “x”.

Another approach is disclosed in Japanese Patent Application No. 2002-284119 (Laid-Open; Apr. 15, 2004), titled “APPARATUS AND METHOD FOR CODING”. This discloses that read out data are sorted by using an algorithm or a table of software in order to detect the lank of magnitude of the data.

A book describes the digital circuit; T. Nakamura, “FUNDAMENTAL OF DIGITAL CIRCUIT” was published by NIPPON RICHO SHUPPANN-KAI on Mar. 20, 2003. In this book, a data processing circuit used to discriminate magnitude between two digital data is described in pp 91-94. For example, the “7485 or 74L85” of TTL, or “4063 or 4585” of CMOS as 4 bits comparator are well known, each of which compares 4 bits data A (a0 to a3) to data B (b0 to b3), and outputs A>B, A<B, or A=B. FIG. 1 is a circuit diagram showing the “74L85”. In this comparator, by operating based on the logic of the 3 bits data (Aj>Bj, Aj<Aj, and Aj=Bj) that are output from upper bit comparator (not shown) and the logic of the input 4 bits data (Ak and Bk; k=0 to 3), outputs 3 bits data (Ak>Bk, Ak<Ak, and Ak=Bk) to lower bit comparator (not shown). That is, by connecting 4 bits comparators in cascade, the data processing can be performed in order to discriminate magnitude between two digital data of multi-bits such as 8 bits, 12 bits, or 16 bits. Further, for example, as an 8 bits comparator, “74682” of TTL. FIGS. 2A and 2B are circuit diagrams of the “74682”.

However, in the above “A fast Algorithm for 3 times 3 Median Filtering” and the same technology described in Japanese Publication No. 2003-3435, since the data processing to compare magnitude of the pixel data by using the software algorithm, the high speed data processing may be difficult due to repeat of data reading and writing.

In the above Japanese Patent Application No. 1996-8090, nine pixel data read out are written in the first memory, and a middle value of each of three pixel data that are read out from the first memory is decided and written in the second memory by the first median filter operator. Then, one middle value of the nine pixel data is decided among the three middle values stored in the second memory by the second median filter operator. Therefore, the high speed data processing may be difficult due to repeat of data reading and writing.

In the above Japanese Patent No. 3,439,306, since means for detecting edge portion of the in input image signal is required, the noise reduction circuit increases in complexity.

In the above Japanese Patent No. 3,463,640, after reading out pixel data of one line and storing them in the line memory, the data processing for reducing noise from each pixel data is performed. Therefore, the high speed data processing may be difficult.

As with above Japanese Patent Applications Nos. 1991-154751 and 2002-284119, reading out pixel data, before the data processing is performed, therefore, the high speed data processing may be difficult.

The 4 bits comparator or 8 bits comparator described in the book; “FUNDAMENTAL OF DIGITAL CIRCUIT” has many wiring patterns, so that high-speed data processing may be difficult due to large RC delay of signals based on stray capacitances between wiring patterns.

### SUMMARY OF THE INVENTION

To solve the problem, an object of the present invention is to provide a data processing circuit for comparing digital data with high speed and, in particular, to provide a median filter and a digital comparator. And an object of the present invention is to provide an integrate circuit incorporating the data processing circuit, and an image processing apparatus including the integrate circuit.

In accordance with the present invention, a digital comparator circuit compares a first data with a predetermined number of bits from a most significant bit to a least significant bit and a second data with the same number of bits inputting from outside. The digital comparator circuit has a plurality of bit comparators corresponding to the number of bits of the first and second data. Each bit comparator includes an input circuit for generating a matching signal (i.e., agreement signal) when the values between a first 1 bit data and a second 1 bit data are equal, while a mismatch signal (i.e., disagreement signal) when the values between the first 1 bit data and the second 1 bit data are unequal; a receiving circuit for receiving a matching signal or a mismatch signal transmitted from an upper bit comparator or a fixed signal generated by a predetermined electronics component; a transmitting circuit for transmitting a mismatch signal to a lower bit comparator when the input circuit generates the mismatch signal or the receiving circuit receives the mismatch signal, while a matching signal to the lower bit comparator when the input circuit generates the matching signal and the receiving circuit receives the matching signal or the fixed signal; and an output circuit for outputting the first 1 bit data being input to the input circuit when the input circuit generates the mismatch signal and the receiving circuit receives the matching signal or the fixed signal.

In accordance with the present invention, a median filer circuit for processing data having 2n+1 pixel data (n is one or more integers) consisting of a sequentially specified one pixel data among a number of pixel data stored in an image memory circuit with two-dimensional style and surrounding pixel data adjacent to the specified pixel data. The median filer circuit includes a data processing circuit including 2n+1 pixel storage circuits with cascade connection each storing one pixel data; a storage control circuit, when 2n+1 pixel data are sequentially read out one by one, for comparing a value of the read out pixel data and each value of currently stored pixel data in the 2n+1 pixel storage circuits, and designating one pixel storage circuit to store the read out pixel data so as to store 2n+1 pixel data in ascending or descending order; and a rewriting control circuit, when after the read out 2n+1 pixel data have been stored in the 2n+1 pixel storage circuits in ascending or descending order based on the designation of the storage control circuit, for replacing the specified pixel data with the pixel data stored in the nth pixel storage circuit in response to a predetermined input rewriting signal.

In accordance with the present invention, an integrate circuit (IC) incorporates the digital comparator circuit into one-chip semiconductor.

In accordance with the present invention, an image processing apparatus has the integrate circuit incorporating the digital comparator circuit into one-chip semiconductor.

A digital comparator circuit, a median filter circuit, an integrate circuit, and an image processing apparatus in accordance with the present invention allow to process data with a significant high-speed.

### BRIEF DESCRIPTION OF THE DRAWINGS

FIG. 1 is a circuit diagram showing a conventional 4 bits comparator circuit;

FIGS. 2A and 2B are circuit diagrams showing a conventional 8 bits comparator circuit;

FIG. 3 is a schematic block diagram showing a data processing circuit of a first embodiment in accordance with the present invention;

FIGS. 4A to 4C are circuit diagrams showing a median filter circuit in FIG. 3;

FIGS. 5A to 5C are exemplary of pixel data processed by the circuit in FIGS. 4A to 4C;

FIG. 6 is timing chart showing data processing of the circuit in FIGS. 4A to 4C;

FIG. 7 is a circuit diagram showing a data processing circuit of a second embodiment in accordance with the present invention;

FIG. 8 is a circuit diagram showing a partial circuit in FIG. 7;

FIG. 9 is a circuit diagram showing a 4 bits comparator of a third embodiment in accordance with the present invention;

FIG. 10 is a schematic block diagram showing a 12 bits comparator with cascade connection of 4 bits comparators in FIG. 9; and

FIG. 11 is a circuit diagram showing an 8 bits comparator of a third embodiment in accordance with the present invention.

### DETAILED DESCRIPTION OF THE PREFERRED EMBODIMENTS

A first, a second and a third embodiments of the present invention will be described in detail below with reference to the accompanying drawings. In addition, a system using an image processing apparatus in accordance with the present invention is, for example, a cellar phone, a digital still camera, a video camera, a television receiver or the like; however, the present invention does not limit to such image processing apparatus. Various modifications will remain readily apparent to those skilled in the art, since the generic principles of the present invention have been defined herein specifically to provide a data processing circuit.

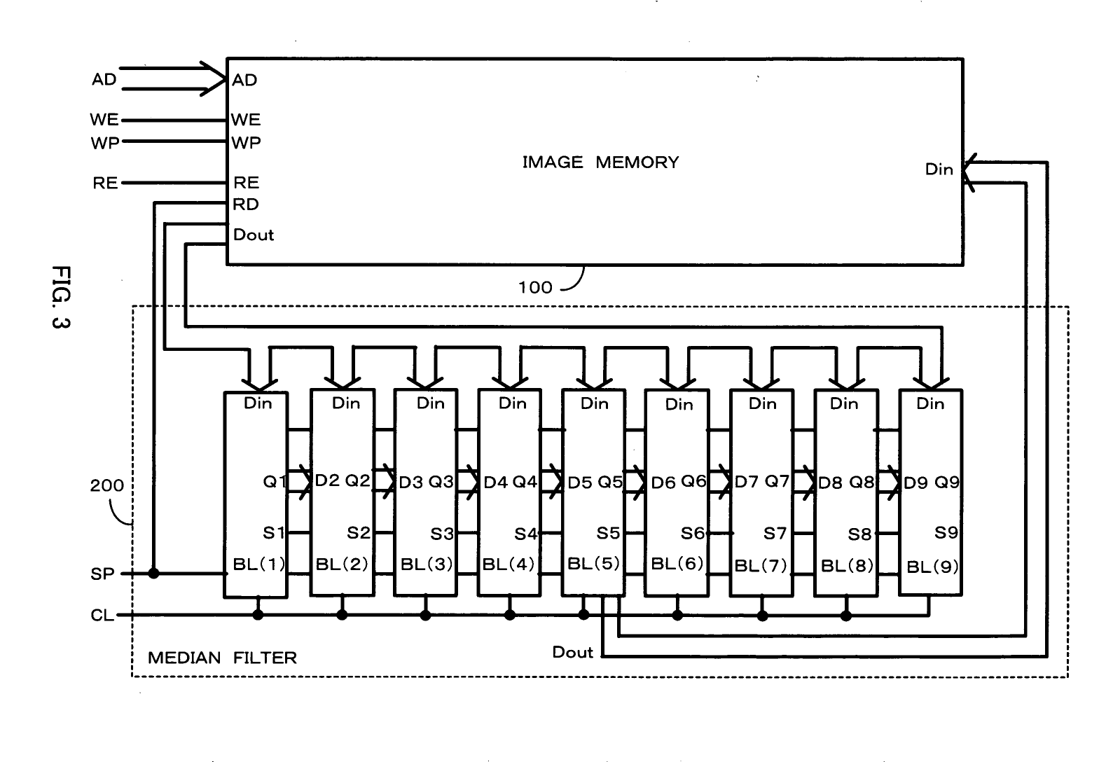

A first embodiment of a data processing device will be described with reference to FIGS. 3 to 6.

FIG. 3 is a schematic block diagram of a one-chip IC to be incorporated into an image processing apparatus (not shown), which is required to remove noise components included in image data. The image processing apparatus includes an image memory 100 that allows storing a screenful two-dimensional pixel data and a median filter 200 that removes noise from specified one pixel data by performing median filtering on nine pixel data. In addition, an electronics circuit (not shown) inputs various kind of signals, described in detail below, to the image memory 100 and median filter 200. However, such electronics circuit is omitted because of the well-known device.

In FIG. 3, the image memory 100 has different data ports consisting of an output port Dout for outputting pixel data and an input port Din for writing pixel data. However, the output port and input port may be a common port. Any way, a mode that reads pixel data out from a storage area designated by an address port AD and a mode that writes pixel data into a storage area designated by an address port AD are based on an independent memory access function respectively.

In the image memory 100, a pixel data of a storage area designated by an address port AD can be read out from the output port Dout, when an enable signal RE being input to a port RE is high-level and when a rise timing of an input read signal RD being input to a port RD. A pixel data can be written into a storage area designated by an address port AD from the input port Din, when an enable signal WE being input to a port WE is high-level and when a rise timing of an input write signal WP being input to a port WP.

If the value of pixel data is a range from 1 to 255 and no pixel data is 0, pixel data are represented as 8 bits digital data; while if the value of pixel data is a range from 1 to 65535 and no pixel data is 0, pixel data are represented as 16 bits digital data. In this embodiment, assume that the value of pixel data is the range from 1 to 255 (i.e., pixel data are represented as 8 bits digital data).

The median filter 200 includes register blocks BL(1) to BL(9). The output port Dout of the image memory 100 is commonly coupled to each register block. One register block can store one pixel data. The output port Dout of the previously designated register block BL(5) is coupled to the input port Din of the image memory 100. Further, a shift signal SP and a clear signal CL are input to the median filter 200 from the electronics circuit being not shown.

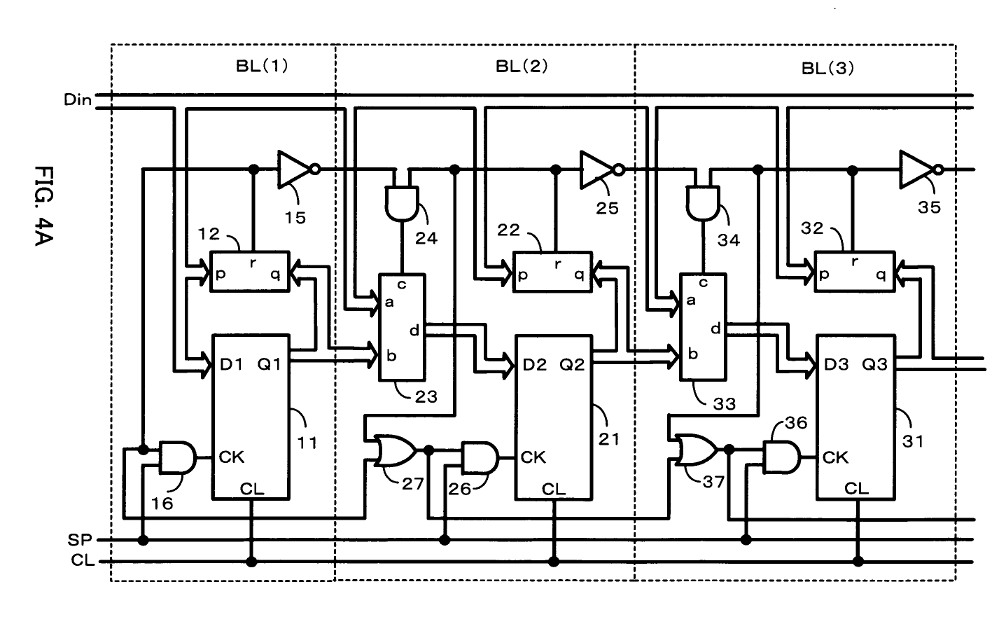

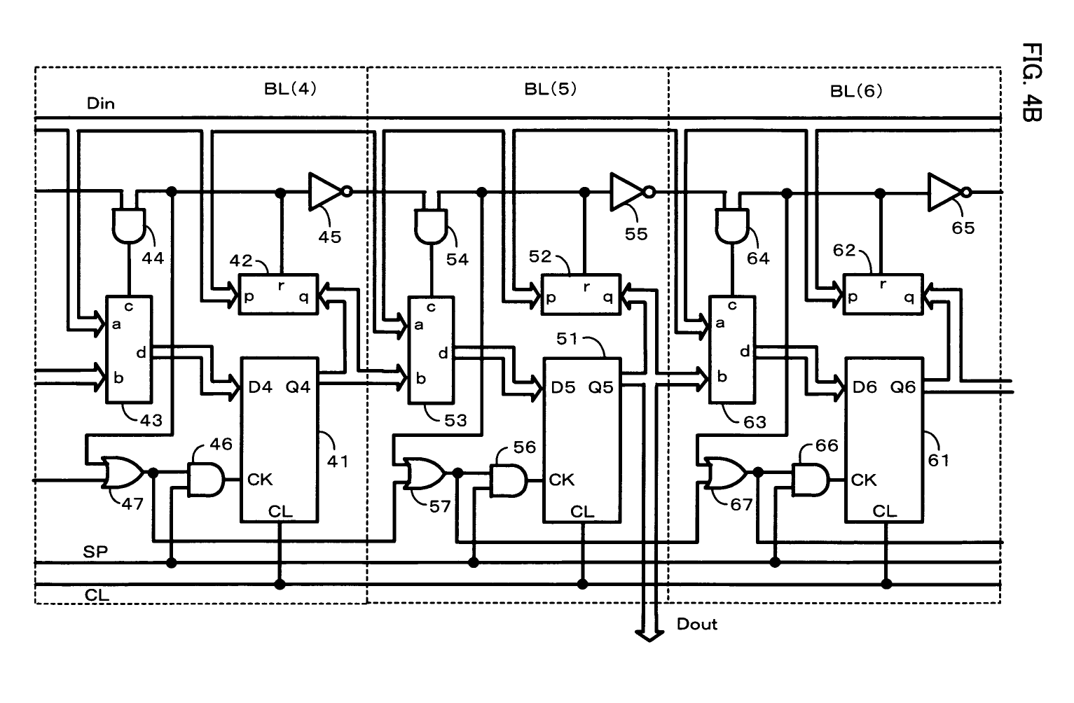

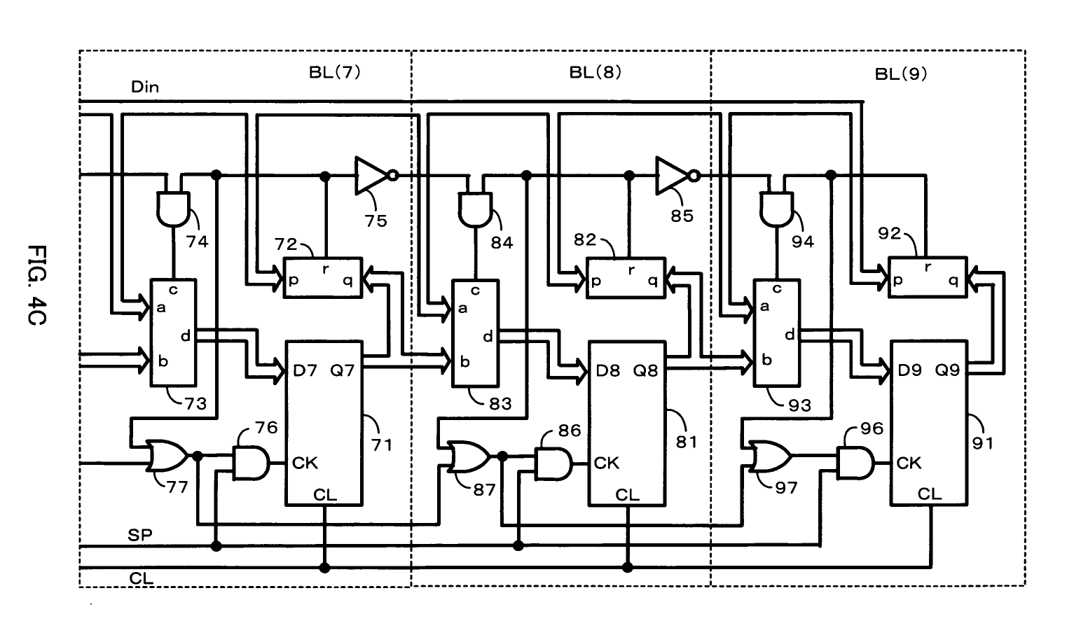

FIGS. 4A to 4C are circuit diagrams showing the median filter 200. FIG. 4A is a circuit diagram of the register blocks BL(1) to BL(3); FIG. 4B is a circuit diagram of the register blocks BL(4), following BL(3), to BL(6); and FIG. 4C is a circuit diagram of the register blocks BL (7) following BL(6), to BL(9).

The function of the median filter 200 in FIGS. 4A to 4C will be described below. The register block BL(1) comprises a register 11, a comparator 12, an inverter gate 15, and an AND gate 16. The input terminal D1 of the register 11 and the input terminal p of the comparator 12 are both coupled to the output port Dout of the image memory 100. The register 11 stores a pixel data provided to the input terminal D1 at fall timing of the shift signal SP input to the trigger terminal CK. The stored pixel data can be read out from the output terminal Q1, which is coupled to the input terminal q of the comparator 12. The comparator 12 compares a value of a pixel provided to the input terminal p, which is read out from the image memory 100 and provided to the input terminal D1 of the register 11, and the value of the pixel data provided to the terminal q from the output terminal Q1, which is stored in the register 11. When the value of the pixel data read out from the image memory 100 is greater than that of the pixel data stored in the register 11, the comparator 12 outputs the comparison signal with high-level (also referred to herein as “positive logic”) from the output terminal r. On the other hand, when the value of the pixel data read out from the image memory 100 is smaller than or equal to that of the pixel data stored in the register 11, the comparator 12 outputs the comparison signal with low-level (also referred to herein as “negative logic”) from the output terminal r. The inverter gate 15 inverts the logic of the comparison signal output from the terminal r of the comparator 12 and outputs it to the next register block BL(2). The AND gate 16 enables the shift signal SP input to the trigger terminal CK of the register 11 when the comparison signal output from the comparator 12 is high-level; while it disables the shift signal SP when the comparison signal is low-level.

The register block BL(2) comprises a register 21, a comparator 22, a switch 23, an AND gate 24, an inverter gate 25, an AND gate 26, and on OR gate 27. The input terminal D2 of the register 21 is coupled to the output d of the switch 23. The register 21 stores a pixel data provided to the input terminal D2 at fall timing of the shift signal SP input to the trigger terminal CK. The stored pixel data can read out from the output terminal Q2, which is coupled to the input terminal q of the comparator 22. The comparator 22 compares the value of the pixel data that is read out from the image memory 100 and the value of the pixel data stored in the register 21. When the value of the pixel data read out from the image memory 100 is greater than that of the pixel data stored in the register 21, the comparator 22 outputs the comparison signal with high-level from the output terminal r. On the other hand, when the value of the pixel data read out from the image memory 100 is smaller than or equal to that of the pixel data stored in the register 21, the comparator 12 outputs the comparison signal with low-level from the output terminal r. The AND gate 24 provides the select signal with high-level to the control terminal c of the switch 23 when the comparison signal output from the comparator 22 is high-level and the output signal from the inverter gate 15 of the previous register block BL(1) is high-level; while it provides the select signal with low-level to the control terminal c when the comparison signal is low-level or the output signal from the inverter gate 15 is low-level. The switch 23 selects the pixel data read out from the image memory 100 and provides it to the input terminal D2 of the register 21, when the select signal provided to the control terminal c is high-level; while it selects the pixel data stored in the register 11 of the previous BL(1) and provides it to the input terminal D2, when the select signal is low-level. The OR gate 27 outputs the signal with high-level, when the comparison signal output from the comparator 22 is high-level or the comparison signal output from the comparator 12 of the previous BL(1) is high-level. The AND gate 26 enables the shift signal SP input to the trigger terminal CK of the register 21, when the signal output from the OR gate 27 is high-level; while it disables the shift signal SP, when the signal is low-level. The inverter gate 25 inverts the logic of the comparison signal output from the terminal r of the comparator 22 and outputs it the next BL(3).

The register block BL(3) comprises a register 31, a comparator 32, a switch 33, an AND gate 34, an inverter gate 35, an AND gate 36, and an OR gate 37. The OR gate 37 outputs the signal with high-level to the AND gate 36, when the comparison signal output from the comparator 32 is high-level or the signal output from the OR gate 27 of the previous BL(2) is high-level. Other functions of the register block BL(3) are the same just as those of the register block BL (2), therefore, the description is omitted to avoid overlaps.

The configurations of the register blocks BL(4) and BL(6) in FIG. 4B and the register blocks BL(7) and BL(8) in FIG. 4C are the same just as those of the register blocks BL(2) and BL(3) in FIG. 4A. Further, The configurations of the register blocks BL(5) in FIG. 4B and the register blocks BL(9) in FIG. 4C are similar to those of the register blocks BL(2) and BL(3) in FIG. 4A, except some ones.

Therefore, the functions of the register blocks BL(4) to BL(9) will be described on the whole. Herein referred to “m” is as one number of 4 to 9 corresponding to BL(4) to BL(9), i.e., BL(m).

The input terminal Dm of the register m1 is coupled to the output d of the switch m3. The register m1 stores a pixel data provided to the input terminal Dm at fall timing of the shift signal SP input to the trigger terminal CK. The stored pixel data can be read out from the output terminal Qm, which is coupled to the input terminal q of the comparator m2. The comparator m2 compares the value of the pixel data that is read out from the image memory 100, which is provided to the input terminal p, and the value of the pixel data stored in the register m1, which is provided to the input terminal q. When the value of the pixel data read out from the image memory 100 is greater than that of the pixel data stored in the register m1, the comparator m2 outputs the comparison signal with high-level from the output terminal r. On the other hand, when the value of the pixel data read out from the image memory 100 is smaller than or equal to that of the pixel data stored in the register m1, the comparator m2 outputs the comparison signal with low-level from the output terminal r. The AND gate m4 provides the select signal with high-level to the control terminal c of the switch m3, when the comparison signal output from the comparator m2 is high-level and the output signal of the inverter gate (m−1) 5 of the previous BL(m−1) is high-level; while it provides the select signal with low-level to the control terminal c, when the comparison signal is low-level or the output signal of the inverter gate (m−1) 5 is low-level. The switch m3 selects the pixel data read out from the image memory 100 and provides it to the input terminal Dm of the register m1, when the select signal provided to the control terminal c is high-level; while it selects the pixel data stored in the register (m−1) 1 of the previous BL (m−1) and provides it to the input terminal Dm, when the select signal is low-level. The OR gate m7 outputs the signal with high-level, when the comparison signal output from the comparator m2 is high-level or the signal output from the OR gate (m−1) 7 of the previous BL (m−1) is high-level. The AND gate m6 enables the shift signal SP input to the trigger terminal CK of the register m1, when the signal output from the OR gate m7 is high-level; while it disables the shift signal SP, when the signal is low-level.

The inverter gates 45 to 85 invert the logic of the comparison signals from the comparators 42 to 82 and provide them to the next register blocks BL(5) to BL(9). However, the final register block BL(9) has no inverter gate that inverts the logic of the comparison signal from the comparator 92. Further, as described about FIG. 3, in the 5th register block BL(5), the output terminal Q5 of the register 51 is coupled to the input port Din of the image memory 100.

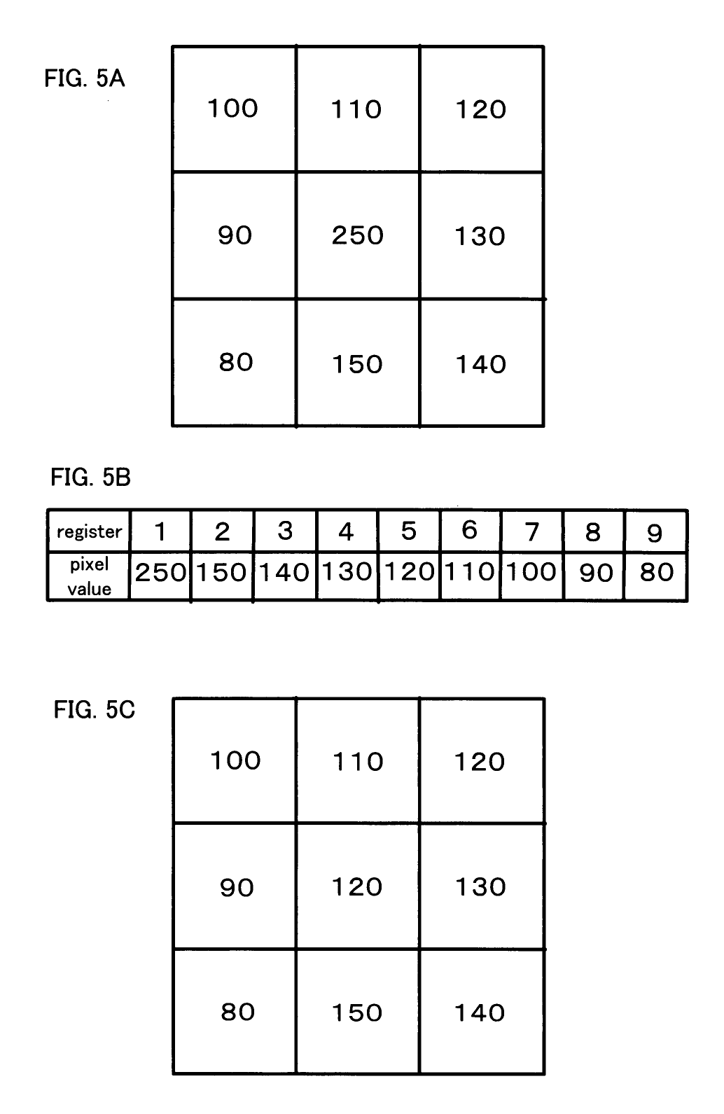

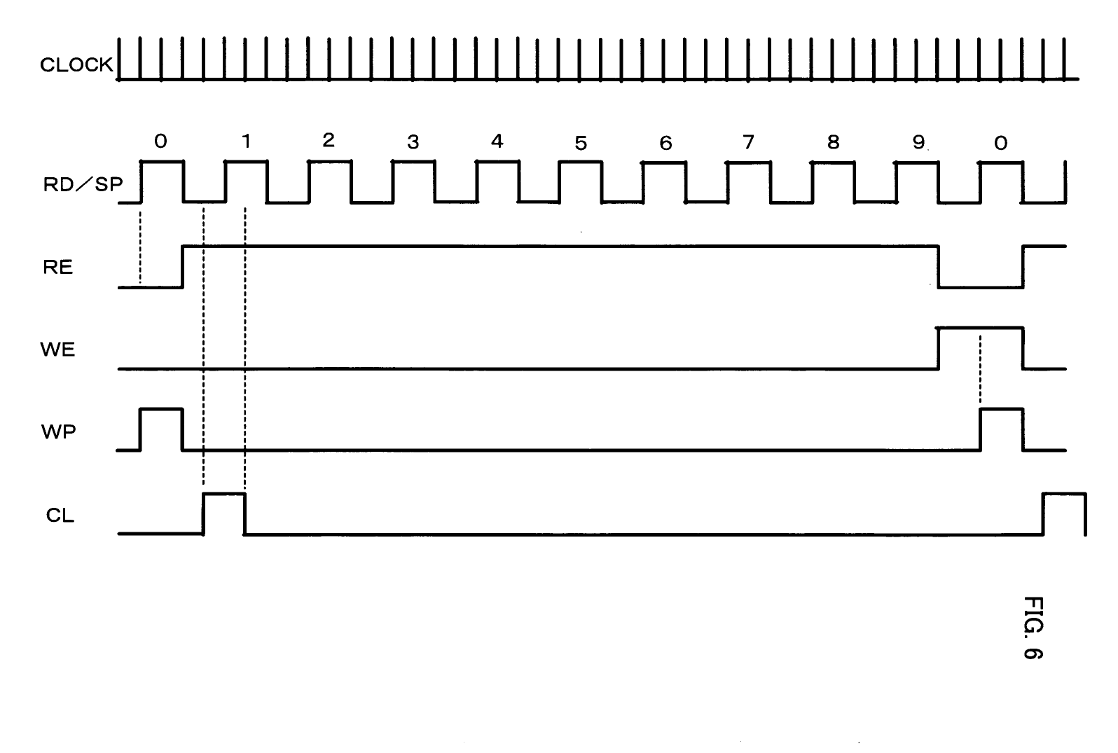

Next, the operation of the image memory 100 and median filter 200 shown in FIGS. 3 and 4A to 4C will be described in detail with reference to a concrete example of pixel data showing in FIGS. 5A to 5C.

FIG. 5A shows values of nine pixel data that are targets of the median filtering. The center pixel data of the FIG. 5A is the designating one as target of noise reduction. The median filter 200 performs the median filtering between the center pixel data and the surrounding eight pixel data. The median filter 200 can read out the nine pixel data from the image memory 100 with any sequence. In FIG. 5A, for example, the median filter 200 may first read out the designated pixel data (i.e., center pixel data), then sequentially readout above left, above, above right, left, right, below left, below, and below right pixel data. Alternatively, it may sequentially read out above left, left, below left, above, center (i.e., designated pixel data), below, above right, right, and below right pixel data. Alternatively, it may clockwise read out, e.g., above right, right, below right, below, below left, left, above left, above, and center pixel data; or may counterclockwise readout. In this case, the median filter 200 first reads out the designated pixel data, then above left, above, above right, left, right, below left, below, and below right pixel data. If the designated pixel data locates the border storage area of the image memory 100, the surrounding pixel data is less than eight. In this case, the median filter 200 repeatedly reads out the same pixel data among three or five surrounding pixel data, until the number of reading times reaches eight.

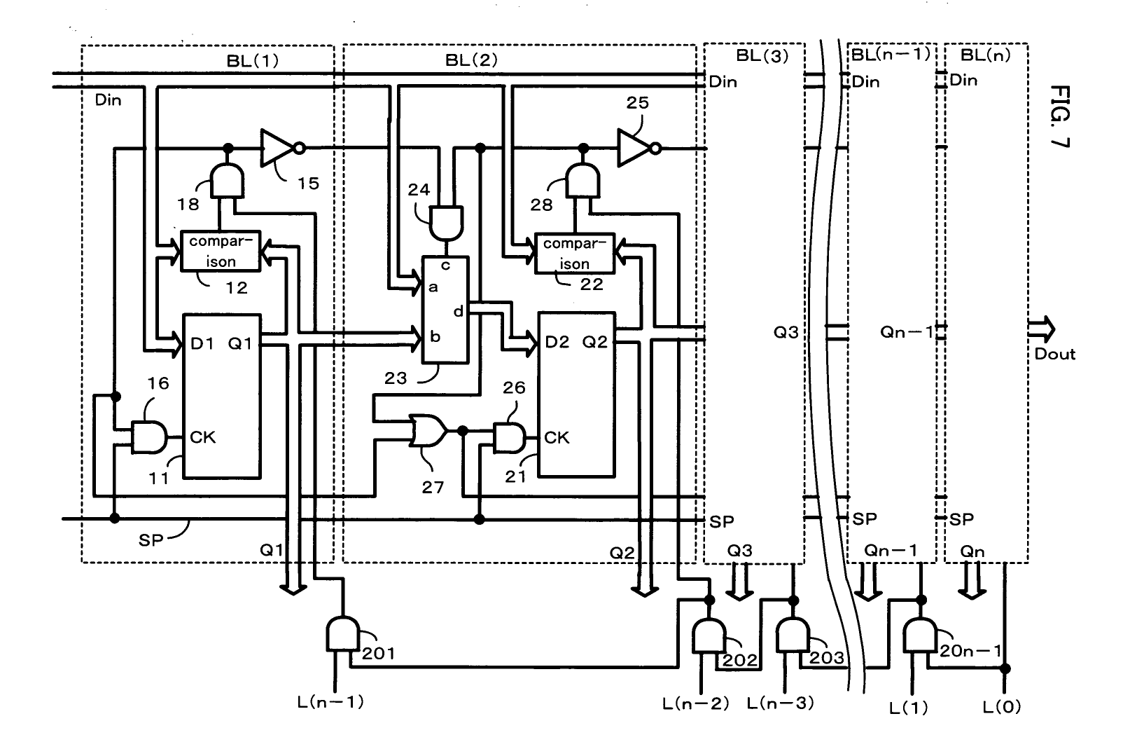

FIG. 6 shows timing chart of pulse signals generated from the electronic circuit being not shown. In FIG. 6, CLOCK is a periodic signal with a constant interval, which is a time-base signal for other pulse signals. RD/SP is a pulse signal with quadruple periodicity of the CLOCK. As described in FIG. 3, the pixel data stored in the image memory 100 is read out and provided to each register block of the median filter 200 at the rise timing of the RD/SP pulse signals (also referred to herein as “RD pulse signals”) when the read enable signal RE is high-level. That is, among the RD pulse signals represented by “0” to “9”, the pixel data is not read out at the rise timing of the RD pulse signal “0”, because the read enable signal RE is low-level. The pixel data in FIG. 5A are sequentially read out at rise timing of the RD pulse signals “1” to “9”, when the read enable signal RE is high-level.

The fall timing of RD/SP pulse signals are defined as the shift signals input to each register blocks BL(1) to BL(9). Therefore, the fall timing of the RD/SP pulse signals (also referred to herein as “SP pulse signals”) “1” to “9” become the shift signals input to each register blocks BL(1) to BL(9). The CL pulse signal is input to the register blocks BL(1) to BL(9) between the RD pulse signal “1” (i.e., rise timing) and SP pulse signal “1” (i.e., fall timing), so that the nine pixel data currently stored in the register blocks BL(1) to BL(9) are all cleared to zeros. Also when this image processing apparatus is initialized by the power on, the register blocks BL(1) to BL(9) are all cleared to zeros. That is, the nine registers 11 to 91 store “0” by the CL pulse signal, before nine pixel data are sequentially read out.

When the first pixel data (value is “100”) read out from the image memory 100 is provided to each of the register blocks BL(1) to BL(9) at the rise timing of the RD pulse signal “1”, the comparators 12 to 92 compare the data “0” stored in the registers 11 to 91 and the pixel data whose value is “100” read out respectively. Then, the comparators 12 to 92 output the comparison signals with high-level from the output terminals r, because the latter to each terminal p is greater than the former to each terminal q. As a result of this, the inverter gates 15 to 85 input low-level signals to the AND gates 24 to 94. Then, the AND gates 24 to 94 provides low-level signals to the switches 23 to 93. Therefore, the input terminals D2 to D9 of the registers 21 to 91 receive the data “0” stored in the previous registers 11 to 81 by selecting of the switches 23 to 93 respectively. The AND gate 16 and OR gate 27 both receive the comparison signal with high-level from the output terminal r of the comparator 12. Therefore, the OR gates 37 to 97 sequentially receive high-level signals from the previous OR gates 27 to 87 respectively, so that the shift signal SP input to the registers 11 to 91 in common is enabled. As a result of this, upon the fall timing of the SP pulse signal “1”, the register 11 stores the first pixel data whose value is “100” read out from the image memory 100 and the other registers 21 to 91 store the data whose values are “0” transferred from the previous registers 11 to 81.

Next, when the second pixel data (value is “110”) read out from the image memory 100 is provided to each of the register blocks BL(1) to BL(9) at the rise timing of the RD pulse signal “2”, the comparator 12 compares the pixel data whose value is “100” stored in the register 11 and the pixel data whose value is “110” read out. Then, the comparator 12 outputs the comparison signal with high-level from the output terminal r, because the latter to the terminal p is greater than the former to the terminal q. Simultaneously, the comparators 22 to 92 compare the data “0” stored in the registers 21 to 91 and the pixel data whose value is “110” read out respectively. Then, the comparators 22 to 92 output the comparison signals with high-level from the output terminals r respectively, because the latter to each terminal p is greater than the former to each terminal q. As a result of this, the inverters 15 to 85 output low-level signals to the AND gates 24 to 94 respectively. Then, the AND gates 24 to 94 provides the select signals with low-level to the switches 23 to 93 respectively. Therefore, the input terminal D2 of the register 21 receives the pixel data whose value is “100” stored in the previous register 11 by selecting of the switch 23. The input terminals D3 to D9 of the registers 31 to 91 receive the data “0” stored in the previous registers 21 to 81 by selecting of the switches 33 to 93 respectively. Further, the AND gate 16 and OR gate 27 both receive the comparison signal with high-level from the output terminal r of the comparator 12. Therefore, the OR gates 37 to 97 sequentially receive high-level signals from the previous OR gates 27 to 87 respectively, so that the shift signal SP input to the registers 11 to 91 in common is enabled. As a result of this, upon the fall timing of the SP pulse signal “2”, the register 11 stores the second pixel data whose value is “110” read out from the image memory 100, the register 21 stores the pixel data whose value is “100” transferred from the previous register 11, and the other registers 31 to 91 store the data whose values are “0” transferred from the previous registers 21 to 81 respectively.

Next, when the third pixel data (value is “120”) read out from the image memory 100 is provided to each of the register blocks BL(1) to BL(9) at the rise timing of the RD pulse signal “3”, the comparator 12 compares the pixel data whose value is “110” stored in the register 11 and the pixel data whose value is “120” read out. Then, the comparator 12 outputs the comparison signal with high-level from the output terminal r, because the latter to the terminal p is greater than the former to the terminal q. Simultaneously, the comparator 22 compares the pixel data whose value is “100” stored in the registers 21 and the pixel data whose value is “120” read out. Then, the comparator 22 outputs the comparison signal with high-level from the output terminal r, because the latter to the terminal p is greater than the former to the terminal q. Simultaneously, the comparators 32 to 92 compare the data “0” stored in the registers 31 to 91 and the pixel data whose value is “120” read out respectively. Then, the comparators 32 to 92 output the comparison signals with high-level from the output terminals r respectively, because the latter to each terminal p is greater than the former to each terminal q. As a result of this, the inverters 15 to 85 output low-level signals to the AND gates 24 to 94 respectively. Then, the AND gates 24 to 94 provides the select signals with low-level to the switches 23 to 93 respectively. Therefore, the input terminal D2 of the register 21 receives the pixel data whose value is “110” stored in the previous register 11 by selecting of the switch 23. The input terminal D3 of the register 31 receives the pixel data whose value is “100” stored in the previous register 21 by selecting of the switch 33. The input terminals D4 to D9 of the registers 41 to 91 receive the data “0” stored in the previous registers 31 to 81 by selecting of the switches 43 to 93 respectively. Further, the AND gate 16 and OR gate 27 both receive the comparison signal with high-level from the output terminal r of the comparator 12. Therefore, the OR gates 37 to 97 sequentially receive high-level signals from the previous OR gates 27 to 87 respectively, so that the shift signal SP input to the registers 11 to 91 in common is enabled. As a result of this, upon the fall timing of the SP pulse signal “3”, the register 11 stores the third pixel data whose value is “120” read out from the image memory 100, the register 21 stores the pixel data whose value is “110” transferred from the previous register 11, the register 31 stores the pixel data whose value is “100” transferred from the previous register 21, and the other registers 41 to 91 store the data whose values are “0” transferred from the previous registers 31 to 81 respectively.

Next, when the fourth pixel data (value is “90”) read out from the image memory 100 is provided to each of the register blocks BL(1) to BL(9) at the rise timing of the RD pulse signal “4”, the comparator 12 compares the pixel data whose value is “120” stored in the register 11 and the pixel data whose value is “90” read out. Then, the comparator 12 outputs the comparison signal with low-level from the output terminal r, because the former to the terminal q is greater than the latter to the terminal p. In this case, the AND gate 16 receives the low-level signal from the comparator 12, so that the shift signal SP to the register 11 is disabled. Simultaneously, the comparator 22 compares the pixel data whose value is “110” stored in the registers 21 and the pixel data whose value is “90” read out. Then, the comparator 22 outputs the comparison signal with low-level from the output terminal r, because the former to the terminal q is greater than the latter to the terminal p. In this case, the OR gate 27 receives the low-level signal from the output terminal r of the comparator 12 and the low-level signal from the output terminal r of the comparator 22. As a result of this, the AND gate 26 receives low-level signal from the OR gate 27, so that the shift signal to the register 21 is disabled. Simultaneously, the comparator 32 compares the pixel data whose value is “100” stored in the registers 31 and the pixel data whose value is “90” read out. Then, the comparator 32 outputs the comparison signal with low-level from the output terminal r, because the former to the terminal q is greater than the latter to the terminal p. In this case, the OR gate 37 receives the low-level signal from the OR gate 27 and the low-level signal from the output terminal r of the comparator 32. As a result of this, the AND gate 36 receives low-level signal from the OR gate 37, so that the shift signal SP to the register 31 is disabled. As a result of this, in spite of the fall timing of the SP pulse signal “4”, the registers 11, 21, and 31 do not store the new pixel data but maintain current pixel data whose values are “120”, “110”, and “100” respectively. Further, the inverter gates 15 to 35 of the register blocks BL(1) to BL(3) output high-level signals to the following AND gates 24 to 44 respectively.

Simultaneously, the comparators 42 to 92 compare the data “0” stored in the registers 41 to 91 and the pixel data whose value is “90” read out respectively. Then, the comparators 42 to 92 output the comparison signals with high-level, because the latter to each terminal p is greater than the former to each terminal q. As a result of this, the AND gate 44 receives the high-level signal from the inverter 35 and the high-level signal from the comparator 42. Therefore, the AND gate 44 provides the select signal with high-level to the control terminal c of the switch 43, so that the input terminal D4 of the register 41 receives the pixel data whose value is “90” read out from the image memory 100 by selecting of the switch 43. In this case, the OR gate 47 receives the comparison signal with high-level from the comparator 42, then the shift signal SP to the register 41 is enabled. As a result of this, upon the fall timing of SP pulse signal “4”, the register 41 stores the pixel data whose value is “90” read out.

In this case, since the AND gates 54 to 94 receive low-level signals from the inverters 45 to 85, providing the select signals with low-level to the switches 53 to 93. Therefore, the input terminals D5 to D9 of the registers 51 to 91 receive the data “0” stored in the previous registers 41 to 81 by selecting of the switches 53 to 93 respectively. Further, since the OR gate 57 receives the comparison signal with high-level from the output terminal r of the comparator 52, providing the high-level signal to the AND gate 56 and OR gate 67. Therefore, the OR gates 77 to 97 sequentially receive the high-level signals from the previous OR gates 67 to 87, so that the shift signal SP to the registers 51 to 91 is enabled. As a result of this, upon the fall timing of SP pulse signal “4”, the registers 51 to 91 store the data “0” transferred from the previous registers 41 to 81.

Next, when the fifth pixel data (value is “250”) read out from the image memory 100 is provided to each of the register blocks BL(1) to BL(9) at the rise timing of the RD pulse signal “5”, the comparator 12 compares the pixel data whose value is “120” stored in the register 11 and the pixel data whose value is “250” read out. The comparator 22 compares the pixel data whose value is “110” stored in the register 21 and the pixel data whose value is “250” read out. The comparator 32 compares the pixel data whose value is “100” stored in the register 31 and the pixel data whose value is “250” readout. The comparator 42 compares the pixel data whose value is “90” stored in the register 41 and the pixel data whose value is “250” read out. Simultaneously, the comparators 52 to 92 compare the data “0” stored in the registers 51 to 91 and the pixel data whose value is “250” read out respectively. Then, the comparators 12 to 92 output the comparison signals with high-level from the output terminals r, because the latter to each terminal p is greater than the former to each terminal q. Therefore, since the AND gates 24 to 94 receive the low-level signals from the inverter gates 15 to 85, providing the low-level signals to the control terminals c of the switches 23 to 93. Then, the input terminals D2 to D5 of the registers 21 to 51 receive the pixel data whose values are “120”, “110”, “100”, and “90” stored in the previous registers 11 to 41 by selecting of the switches 23 to 53 respectively. Simultaneously, the input terminals D6 to D9 of the registers 61 to 91 receive the data “0” stored in the pervious registers 51 to 81 by selecting the switches 63 to 93 respectively. In this case, the AND gate 16 and OR gate 27 both receive the comparison signal with high-level from the output terminal r of the comparator 12. Therefore, the OR gates 37 to 97 sequentially receive high-level signals from the previous OR gates 27 to 87, so that the shift signal SP to the registers 11 to 91 is enabled. As a result of this, upon the fall timing of the SP pulse signal “5”, the register 11 stores the pixel data whose value is “250” read out from the image memory 100. The register 21 stores the pixel data whose value is “120” transferred from the previous register 11. The register 31 stores the pixel data whose value is “110” transferred from the previous register 21. The register 41 stores the pixel data whose value is “100” transferred from the previous register 31. The register 51 stores the pixel data whose value is “90” transferred from the previous register 41. And the registers 61 to 91 respectively store the data “0” transferred from the previous register 51 to 81.

Next, when the sixth pixel data (value is “130”) read out from the image memory 100 is provided to each of the register blocks BL(1) to BL(9) at the rise timing of the RD pulse signal “6”, the comparator 12 compares the pixel data whose value is “250” stored in the register 11 and the pixel data whose value is “130” read out. Then, the comparator 12 outputs the comparison signal with low-level from the output terminal r, because the former to the terminal q is greater than the latter to the terminal p. The comparator 22 compares the pixel data whose value is “120” stored in the register 21 and the pixel data whose value is “130” read out. Then, the comparator 22 outputs the comparison signal with high-level from the output terminal r, because the latter to the terminal p is greater than the former to the terminal q. The comparator 32 compares the pixel data whose value is “110” stored in the register 31 and the pixel data whose value is “130” read out. Then, the comparator 32 outputs the comparison signal with high-level from the output terminal r, because the latter to the terminal p is greater than the former to the terminal q. The comparator 42 compares the pixel data whose value is “100” stored in the register 41 and the pixel data whose value is “130” read out. Then, the comparator 42 outputs the comparison signal with high-level from the output terminal r, because the latter to the terminal p is greater than the former to the terminal q. The comparator 52 compares the pixel data whose value is “90” stored in the register 51 and the pixel data whose value is “130” read out. Then, the comparator 52 outputs the comparison signal with high-level from the output terminal r, because the latter to the terminal p is greater than the former to the terminal q. Simultaneously, the comparators 62 to 92 compare the data “0” stored in the registers 61 to 91 and the pixel data whose value is “130” read out respectively. Then, the comparators 62 to 92 output the comparison signals with high-level from the output terminal r, because the latter to each terminal p is greater than the former to each terminal q. In this case, the AND gate 16 receives the comparison signal with low-level from the comparator 12, so that the shift signal SP to the register 11 is disabled. As a result of this, in spite of the fall timing of the SP pulse signal “6”, the registers 11 does not store the new pixel data but maintains current pixel data whose value is “250”.

In this case, since the AND gate 24 receives the high-level signal from the previous inverter 15 and the high-level signal from the comparator 22, providing the select signal with high-level to the control terminal c of the switch 23. Then, the input terminal D2 of the register 21 receives the sixth pixel data whose value is “130” read out from the image memory 100 by selecting of the switch 23. Further, the OR gate 27 receives the comparison signal with high-level signal from the output terminal r of the comparator 22. Therefore, the AND gate 26 receives high-level signal from the OR gate 27, so that the shift signal SP to the register 21 is enabled. As a result of this, the register 21 stores the pixel data whose value is “130” read out.

Further in this case, since the AND gates 34 to 94 receive low-level signals from the previous inverters 25 to 85, providing the low-level signals to the switches 33 to 93. Then, the input terminals D3 to D6 of the registers 31 to 61 receive the pixel data whose values are “120”, “110”, “100”, and “90” stored in the previous registers 21 to 51 by selecting of the switches 33 to 63 respectively. And, input terminals D7 to D9 of the registers 71 to 91 receive the data “0” stored in the previous registers 61 to 81 by selecting the switches 73 to 93 respectively. Further, the OR gate 37 receives high-level signal from the OR gate 27. Therefore, the OR gates 47 to 97 sequentially receive high-level signals from the previous OR gates 37 to 87, so that the shift signal SP to the registers 41 to 91 is enabled. AS a result of this, the registers 31 to 61 store the pixel data whose values are “120”, “110”, “100”, and “90” transferred from the previous registers 21 to 51; the registers 71 to 91 store the data “0” transferred from the previous registers 61 to 81 respectively.

Next, when the seventh pixel data (value is “80”) read out from the image memory 100 is provided to each of the register blocks BL(1) to BL(9) at the rise timing of the RD pulse signal “7”, the comparator 12 compares the pixel data whose value is “250” stored in the register 11 and the pixel data whose value is “80” read out. Then, the comparator 12 outputs the comparison signal with low-level from the output terminal r, because the former to the terminal q is greater than the latter to the terminal p. The comparator 22 compares the pixel data whose value is “130” stored in the register 21 and the pixel data whose value is “80” read out. Then, the comparator 22 outputs the comparison signal with low-level from the output terminal r, because the former to the terminal q is greater than the latter to the terminal p. The comparator 32 compares the pixel data whose value is “120” stored in the register 31 and the pixel data whose value is “80” read out. Then, the comparator 32 outputs the comparison signal with low-level from the output terminal r, because the former to the terminal q is greater than the latter to the terminal p. The comparator 42 compares the pixel data whose value is “110” stored in the register 41 and the pixel data whose value is “80” read out. Then, the comparator 42 outputs the comparison signal with low-level from the output terminal r, because the former to the terminal q is greater than the latter to the terminal p. The comparator 52 compares the pixel data whose value is “100” stored in the register 51 and the pixel data whose value is “80” read out. Then, the comparator 52 outputs the comparison signal with low-level from the output terminal r, because the former to the terminal q is greater than the latter to the terminal p. The comparator 62 compares the pixel data whose value is “90” stored in the register 61 and the pixel data whose value is “80” read out. Then, the comparator 62 outputs the comparison signal with low-level from the output terminal r, because the former to the terminal q is greater than the latter to the terminal p. Simultaneously, the comparators 72 to 92 compare the data “0” stored in the registers 71 to 91 and the pixel data whose value is “80” read out respectively. Then, the comparators 72 to 92 output the comparison signals with high-level from the output terminals r, because the latter to each terminal p is greater than the former to each terminal q.

In this case, the AND gate 16 receives the low-level signal from the output terminal r of the comparator 12, so that the shift signal SP to the register 11 is disabled. The OR gate 27 receives the low-level signal from the output terminal r of the comparator 12 and the low-level signal from the output terminal r of the comparator 22, so that the shift signal SP to the register 21 is disabled. The OR gate 37 receives the low-level signal from the output of the previous OR gate 27 and the low-level signal from the output terminal of the comparator 32, so that the shift signal SP to the register 31 is disabled. The OR gate 47 receives the low-level signal from the output of the previous OR gate 37 and the low-level signal from the output terminal r of the comparator 42, so that the shift signal SP to the register 41 is disabled. The OR gate 57 receives the low-level signal from the output of the previous OR gate 47 and the low-level signal from the output terminal r of the comparator 52, so that the shift signal SP to the register 51 is disabled. The OR gate 67 receives the low-level signal from the output of the previous OR gate 57 and the low-level signal from the output terminal r of the comparator 62, so that the shift signal SP to the register 61 is disabled. As a result of this, in spite of the fall timing of the SP pulse “7”, the registers 11 to 61 do not store the new data but maintain current pixel data whose values are “250”, “130”, “120”, “110”, “100”, and “90”.

Since the AND gate 74 receives the high-level signal from the inverter 65 and the high-level signal from the output terminal r of the comparator 72, providing the select signal with high-level to the control terminal c of the switch 73. Therefore, the input terminal D7 of the register 71 receives the pixel data whose value is “80” read out by selecting the switch 73. In this case, the OR gate 77 receives high-level signal from the output terminal r of the comparator 72, so that the shift signal SP to the register 71 is enabled. As a result of this, upon the fall timing of the SP pulse “7”, the register 71 stores the seventh pixel data whose value is “80” read out. In this case, since the AND gates 84 and 94 receive the low-level signals from the inverters 75 and 85, providing the low-level signals to the switches 83 and 93. Therefore, the input terminals D8 and D9 receive the data “0” stored in the registers 71 and 81 by selecting the switches 83 and 93. In this case, the OR gates 87 and 97 receive the high-level signals from the output terminals r of the comparators 82 and 92, so that the shift signal SP to the registers 81 and 91 is enabled. As a result of this, upon the fall timing of the SP pulse “7”, the registers 81 and 91 store the data “0” transferred from the previous registers 71 and 81.

Next, when the eighth pixel data (value is “150”) read out from the image memory 100 is provided to each of the register blocks BL(1) to BL(9) at the rise timing of the RD pulse signal “8”, the comparator 12 compares the pixel data whose value is “250” stored in the register 11 and the pixel data whose value is “150” read out. Then, the comparator 12 outputs the comparison signal with low-level from the output terminal r, because the former to the terminal q is greater than the latter to the terminal p. The comparator 22 compares the pixel data whose value is “130” stored in the register 21 and the pixel data whose value is “150” read out. Then, the comparator 22 outputs the comparison signal with high-level from the output terminal r, because the latter to the terminal p is greater than the former to the terminal q. The comparator 32 compares the pixel data whose value is “120” stored in the register 31 and the pixel data whose value is “150” read out. Then, the comparator 32 outputs the comparison signal with high-level from the output terminal r, because the latter to the terminal p is greater than the former to the terminal q. The comparator 42 compares the pixel data whose value is “110” stored in the register 41 and the pixel data whose value is “150” read out. Then, the comparator 42 outputs the comparison signal with high-level from the output terminal r, because the latter to the terminal p is greater than the former to the terminal q. The comparator 52 compares the pixel data whose value is “100” stored in the register 51 and the pixel data whose value is “150” read out. Then, the comparator 52 outputs the comparison signal with high-level from the output terminal r, because the latter to the terminal p is greater than the former to the terminal q. The comparator 62 compares the pixel data whose value is “90” stored in the register 61 and the pixel data whose value is “150” read out. Then, the comparator 62 outputs the comparison signal with high-level from the output terminal r, because the latter to the terminal p is greater than the former to the terminal q. The comparator 72 compares the pixel data whose value is “80” stored in the register 71 and the pixel data whose value is “150” read out. Then, the comparator 72 outputs the comparison signal with high-level from the output terminal r, because the latter to the terminal p is greater than the former to the terminal q. Simultaneously, the comparators 82 and 92 compare the data “0” stored in the registers 81 and 91 and the pixel data whose value is “150” read out respectively. Then, the comparators 82 and 92 output the comparison signals with high-level from the output terminals r, because the latter to each terminal p is greater than the former to each terminal q.

In this case, the AND gate 16 receives the comparison signal with low-level from the comparator 12, so that the shift signal SP to the register 11 is disabled. As a result of this, in spite of the fall timing of the SP pulse signal “8”, the register 11 does not store the new pixel data but maintains current pixel data whose value is “250”. Further, since the AND gate 24 receives the high-level signal from the inverter 15 and the high-level signal from the output terminal r of the comparator 22, providing the selecting signal with high-level to the control terminal c of the switch 23. Therefore, the input terminal D2 of the register 21 receives the pixel data whose value is “150” read out by selecting of the switch 23. In this case, the OR gate 27 receives the high-level signal from the output terminal r of the comparator 22. Therefore, the AND gate 26 receives the high-level signal from the OR gate 27, so that the shift signal SP to the register 21 is enabled. As a result of this, upon the fall timing of the SP pulse “8”, the register 21 stores the eighth pixel data whose value is “150” read out from the image memory 100.

Further in this case, the AND gates 34 to 94 receive the low-level signals from the inverters 25 to 85, providing the select signals with low-level to the switches 33 to 93 respectively. Therefore, the input terminals D 3 to D8 of the registers 31 to 81 receive the pixel data whose values are “130”, “120”, “110”, “100”, “90”, and “80” stored in the registers 21 to 71 by selecting of the switches 33 to 83 respectively. And, the input terminal D9 of the register 91 receives the data “0” stored in the register 81 by selecting of the switch 93. And in this case, the OR gate 37 receives the high-level signal to the OR gate 27. Therefore, the OR gates 47 to 97 sequentially receive the high-level signals from the OR gates 37 to 87, so that the shift signal SP to the registers 31 to 91 is enabled. As a result of this, upon the fall timing of the SP pulse “8”, the registers 31 to 81 store the pixel data whose values are “130”, “120”, “110”, “100”, “90”, and “80” transferred from the previous registers 21 to 71; the register 91 stores the data “0” transferred from the previous register 81.

Next, when the ninth pixel data (value is “140”) read out from the image memory 100 is provided to each of the register blocks BL(1) to BL(9) at the rise timing of the RD pulse signal “9”, the comparator 12 compares the pixel data whose value is “250” stored in the register 11 and the pixel data whose value is “140” read out. Then, the comparator 12 outputs the comparison signal with low-level from the output terminal r, because the former to the terminal q is greater than the latter to the terminal p. The comparator 22 compares the pixel data whose value is “150” stored in the register 21 and the pixel data whose value is “140” read out. Then, the comparator 22 outputs the comparison signal with low-level from the output terminal r, because the former to the terminal q is greater than the latter to the terminal p. The comparator 32 compares the pixel data whose value is “130” stored in the register 31 and the pixel data whose value is “140” read out. Then, the comparator 32 outputs the comparison signal with high-level from the output terminal r, because the latter to the terminal p is greater than the former to the terminal q. The comparator 42 compares the pixel data whose value is “120” stored in the register 41 and the pixel data whose value is “140” read out. Then, the comparator 42 outputs the comparison signal with high-level from the output terminal r, because the latter to the terminal p is greater than the former to the terminal q. The comparator 52 compares the pixel data whose value is “110” stored in the register 51 and the pixel data whose value is “140” read out. Then, the comparator 52 outputs the comparison signal with high-level from the output terminal r, because the latter to the terminal p is greater than the former to the terminal q. The comparator 62 compares the pixel data whose value is “100” stored in the register 61 and the pixel data whose value is “140” read out. Then, the comparator 62 outputs the comparison signal with high-level from the output terminal r, because the latter to the terminal p is greater than the former to the terminal q. The comparator 72 compares the pixel data whose value is “90” stored in the register 71 and the pixel data whose value is “140” read out. Then, the comparator 72 outputs the comparison signal with high-level from the output terminal r, because the latter to the terminal p is greater than the former to the terminal q. The comparator 82 compares the pixel data whose value is “80” stored in the register 81 and the pixel data whose value is “140” read out. Then, the comparator 82 outputs the comparison signal with high-level from the output terminal r, because the latter to the terminal p is greater than the former to the terminal q. The comparators 92 compares the data “0” stored in the registers 91 and the pixel data whose value is “140” read out. Then, the comparators 92 outputs the comparison signals with high-level from the output terminal r, because the latter to the terminal p is greater than the former to the terminal q.

In this case, the AND gate 16 receives the comparison signal with low-level from the comparator 12, so that the shift signal SP to the register 11 is disabled. As a result of this, in spite of the fall timing of the SP pulse signal “9”, the register 11 does not store the new pixel data but maintains current pixel data whose value is “250”. And, in this case, the OR gate 27 receives the low-level signal from the output terminal r of the comparator 12 and the low-level signal from the output terminal r of the comparator 22. Therefore, the AND gate 26 receives the low-level signal from the OR gate 27, so that the shift signal SP to the register 21 is disabled. As a result of this, in spite of the fall timing of the SP pulse signal “9”, the register 21 does not store the new pixel data but maintains current pixel data whose value is “150”.

Further, since the AND gate 34 receives the high-level signal from the inverter 25 and the high-level signal from the output terminal r of the comparator 32, providing the selecting signal with high-level to the control terminal c of the switch 33. Therefore, the input terminal D3 of the register 31 receives the pixel data whose value is “140” read out by selecting of the switch 33. In this case, the OR gate 37 receives the high-level signal from the output terminal r of the comparator 32. Therefore, the AND gate 36 receives the high-level signal from the OR gate 37, so that the shift signal SP to the register 31 is enabled. As a result of this, upon the fall timing of the SP pulse “9”, the register 31 stores the ninth pixel data whose value is “140” read out from the image memory 100.

Further in this case, the AND gates 44 to 94 receive the low-level signals from the inverters 35 to 85, providing the select signals with low-level to the switches 43 to 93 respectively. Therefore, the input terminals D 4 to D9 of the registers 41 to 91 receive the pixel data whose values are “130”, “120”, “110”, “100”, “190”, and “80” stored in the registers 31 to 81 by selecting of the switches 43 to 93 respectively. And in this case, the OR gate 47 receives the high-level signal to the OR gate 37. Therefore, the OR gates 57 to 97 sequentially receive the high-level signals from the OR gates 47 to 87, so that the shift signal SP to the registers 41 to 91 is enabled. As a result of this, upon the fall timing of the SP pulse “9”, the registers 41 to 91 store the pixel data whose values are “130”, “120”, “110”, “100”, “90”, and “80” transferred from the previous registers 31 to 81.

Consequently in this case, as shown in FIG. 5B, the register blocks BL(1) to BL(9) store the pixel data whose values are “250”, “150”, “140”, “130”, “120”, “110”, “100”, “190”, and “80”. That is, the nine pixel data that consist of the designated pixel data as the target to reduce noise and the eight surrounding pixel data adjacent to the designated pixel data are stored in the median filter 200 in FIG. 3 in descending order. Therefore, the pixel data whose value is “120” stored in the register 51 of the register block BL(5) in FIG. 4B is the median value.

Further, the write enable signal WE becomes high-level at the fall timing of the SP pulse 11911, so that it is able to write data into the image memory 100 in FIG. 3. At this time, the address signal AD for data writing into the image memory 100 selects the address of the designated pixel data as the target to reduce noise. Simultaneously, the read enable signal RD falls to low-level, so that it is disable to read out from the image memory 100. That is, in spite of rise timing of the RD pulse “0” following the RD pulse “9”, the pixel data is not read out. Further, the write signal WP becomes high-level at the same timing as the rise timing of the RD pulse “0”. As a result of this, the current value “250” of the designated pixel data as the target to reduce noise in the image memory 100 is replaced to the median value “120” of the pixel data stored in the register 51. Next, since the clear signal CL is input to the median filter 200, the pixel data stored in all registers 11 to 91 are cleared, before the first pixel data among the next nine pixel data is read out from the image memory 100 at the fall timing of the SP pulse “1”, which is the shift signal.

In this way, according to the first embodiment described above, when the nine pixel data, which consist of the designated pixel data as the target to reduce noise and the eight surrounding pixel data adjacent to the designated pixel data, read out from the image memory 100 are stored in the median filter 200 in synchronization with the RD/SP pulses, the median value among these nine pixel data is automatically decided. Then, the value of the designated pixel data as the target to reduce noise is replaced to the median value. That is, with only reading out nine pixel data and without requirement of any other data processing, noise can be reduced from the designated pixel data. Therefore, the first embodiment provides a data processing circuit in a system for comparing digital data with high speed.

In addition, in the first embodiment above, the registers 11 to 91 store nine pixel data in descending order; however, which may store nine pixel data in ascending order. If so, the comparators 12 to 92 output the comparison signals with high-level when the pixel data read out is smaller than the data stored in the registers 11 to 91 respectively.

As described above, if the designated pixel data locates the border storage area of the image memory 100, the surrounding pixel data is less than eight. In FIG. 5A, for example, if the designated pixel data is one whose value is “100”, then the surrounding pixel data adjacent to the designated pixel data are only three whose values are “110”, “250”, and “90”. In this case, the median filter 200 repeatedly reads out these three pixel data, until the number of reading times reaches eight.

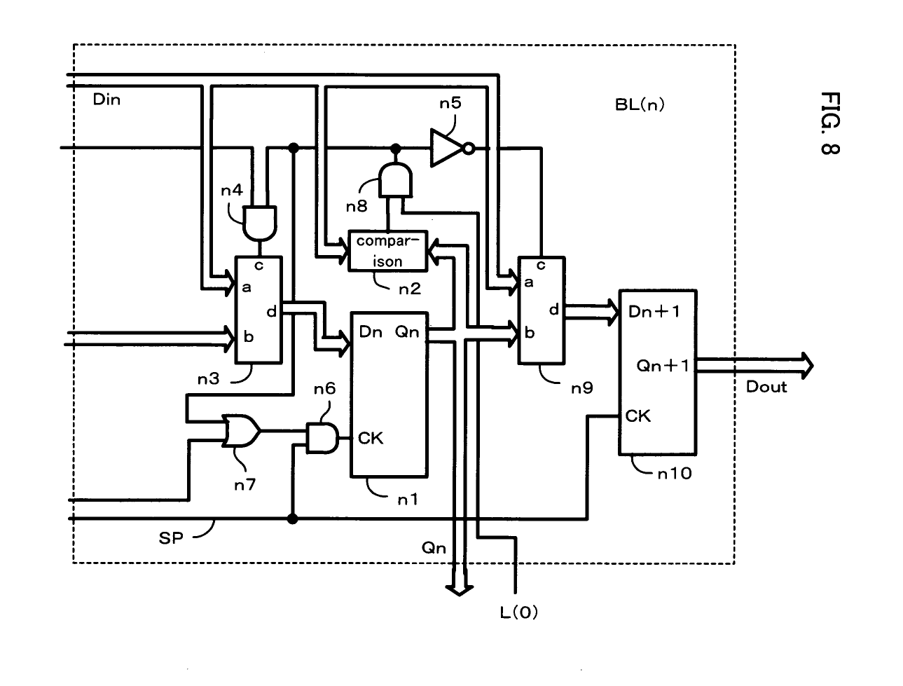

Next, a data processing circuit of a second embodiment will be described in detail below, with reference to FIGS. 7 and 8.

FIG. 7 is a circuit diagram showing a data processing circuit of the second embodiment in accordance with the present invention, which stores “n” input data (n is two or more) in descending order. The data to be stored has a plurality of bits such as 4 bits, 8 bits, 12 bits, 16 bits, 32 bits or the like; however, kinds of data is not limited. That is, the data processed is not only the pixel data in the first embodiment but also other data such as audio data, measurement data, and search data used for database systems.

The basic configuration of the second embodiment is much the same as that of the median filter 200 in the first embodiment, so that the common components are represented by the same numeric characters, and the overlapped description will be omitted except requirements.

The data processing circuit of the second embodiment has register blocks BL(1) to BL(n), which are indicated by dotted line frames in FIG. 7. The inner circuits of the register blocks BL(3) to BL(n−1), though only being indicated by dotted line frames, are the same as those of the register block BL(2). In contrast to this, the register blocks BL(1) and BL(n) are some different from the register block BL(2). FIG. 8 shows the inner circuit of the register block BL(n) in FIG. 7.

It is useful for understanding to compare the register blocks between the first embodiment shown in FIGS. 4A to 4C and the second embodiment in FIGS. 7 and 8.

The inner circuit of the register block (1) of the second embodiment is different from that of the register block (1) of the first embodiment in that; adding a AND gate 18 in which an output is connected to an output terminal of a comparator 12 and a AND gate 201 in which output is connected to another input of the AND gate 18; and allowing to read out data stored in a register 11 from an output terminal Q1. Also the inner circuit of the register block (2) of the second embodiment is different from that of the register block (2) of the first embodiment in that; adding a AND gate 28 in which an output is connected to an output terminal of a comparator 22 and an AND gate 202 in which an output is connected to another input of the AND gate 28; and allowing to read out data stored in a register 21 from an output terminal Q2.

There is not shown in FIG. 7, however, as with the inner circuit of the register block (m; which is one of 3 to n−1) of the second embodiment is different from that of the register block (m) of the first embodiment in that; adding a AND gate m8 in which an output is connected to an output terminal of a comparator m2 and a AND gate 20m in which an output is connected to another input of the AND gate m8 and to an input of an AND gate 20m−1 of the previous block; and allowing to read out data stored in a register m1 from an output terminal Qm.

Further, in FIG. 8, the inner circuit of the last register block (n) comprises a register n1, a comparator n2, a switch n3, an AND gate n4, an inverter gate n5, an AND gate n6, an OR gate n7, an AND gate n8, a switch n9, and a register n10.

As shown in FIG. 8, the inner circuit of the register block (n) is different from that of the register block (2) in FIG. 7 in that; adding the switch n9 in which one input terminal a is connected to the data bus Din, another input terminal b is connected to an output terminal Qn of the register n1, and a control terminal c is connected to the inverter n5; and adding the register n10 in which a data input terminal Dn+1 is connected to an output terminal d of the switch n9, a clock input terminal CK receives the shift signal SP, and an output terminal Dout is connected to outside circuit (not shown). Further, the register block (n) has not AND gate corresponding to the AND gate 202 of the register block (2).

Signals L(0) to L(n−1) from outside circuit (not shown) are input to the data processing circuit in FIG. 7. The signal L(0) is input to the AND gate n8 in FIG. 8 and the AND gate 20n−1 in FIG. 7. Signals L(1) to L(n−1) are input to the AND gates 20n−1 to 201 respectively.

Next, the operation of the data processing circuit shown in FIGS. 7 and 8 will be described in detail below.

If the signal L(n−1) with low-level is input to the AND gate 201 of the register block (1), then the AND gate 18 receives the low-level signal from the AND gate 201. Therefore, the AND gate 16 receives the low-level signal from the AND gate 18 regardless of the output signal from the comparator 12, so that the shift signal SP to the register 11 is disabled. As a result of this, the register 11 does not store data from the data bus Din. That is, the data processing circuit in FIG. 7 is stores (n−1) data in the register blocks BL(2) to BL(n) in descending order.

If the signal L(n−2) with low-level is input to the AND gate 202 of the register block (2), then the AND gates 201 and 28 receive the low-level signal from the AND gate 202. Continuously, the AND gate 18 receives the low-level signal from the AND gate 201. Therefore, the AND gate 16 receives the low-level signal from the AND gate 18, and the OR gate 27 receives the two low-level signals from the AND gates 18 and 28 respectively, so that the shift signal SP to the registers 11 and 21 is disabled. As a result of this, the registers 11 and 21 do not store data from the data bus Din. That is, the data processing circuit in FIG. 7 is stores (n−2) data in the register blocks BL(3) to BL(n) in descending order.

In this way, if an optionally selected signal L(n−i) with low-level is input to the AND gate 20i, then the shift signal SP to the registers 11 to i1 of the blocks BL(1) to BL(i) is disabled. And then, the registers 11 to i1 do not store data from the data bus Din. As a result of this, other registers BL(i−1) to BL(n) store (n−i) data in descending order.

If all signals L(n−1) to L(0) with high-level are input to the register blocks BL(1) to BL(n), then the nth data in descending order is stored in the register BL (n); all data being less than the nth data are output to outside via the register n10 without storing.

In contrast of this, if all signals L(n−1) to L(0) with low-level are input to the register blocks BL(1) to BL(n), then the shift signal to register blocks BL(1) to BL(n) is disabled. As a result of this, all data are passed through this data processing circuit and output to outside via the register n10.

As shown in FIGS. 7 and 8, stored data in the registers 11 to n1 can be read out from the output terminals Q1 to Qn. Therefore, when n data have been stored in this data processing circuit, any ordinal data can easily be read out. For example, when twenty-five data have been stored in this data processing circuit, 13th data as the median value can easily be read out.

In addition, in the second embodiment above, the registers 11 to n1 store n data in descending order; however, which may store n data in ascending order. If so, the comparators 12 to n2 output the comparison signals with high-level when the data read out is smaller than the data stored in the registers 11 to n1 respectively.

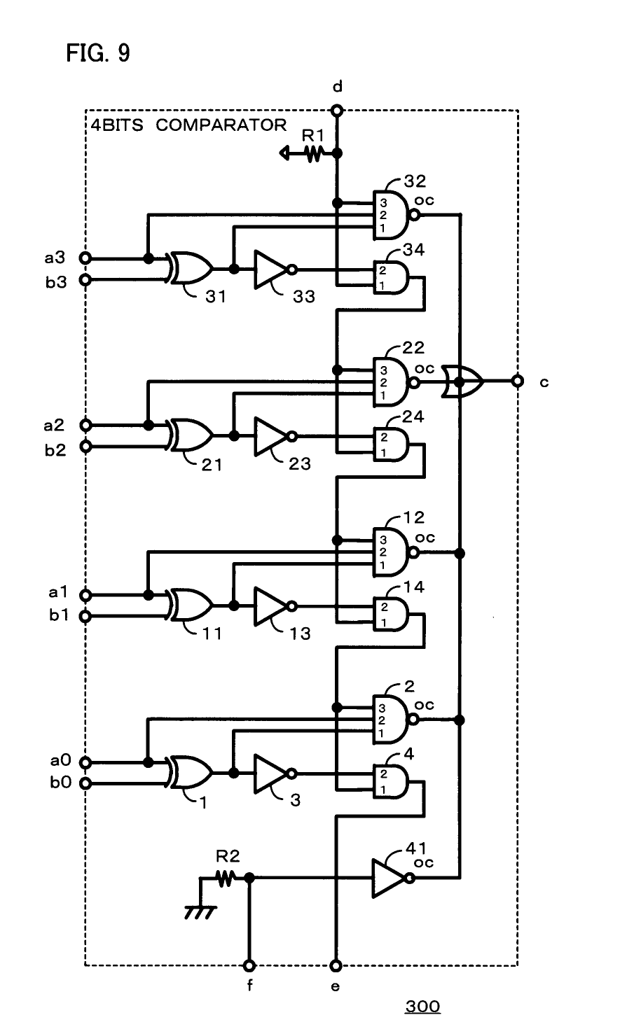

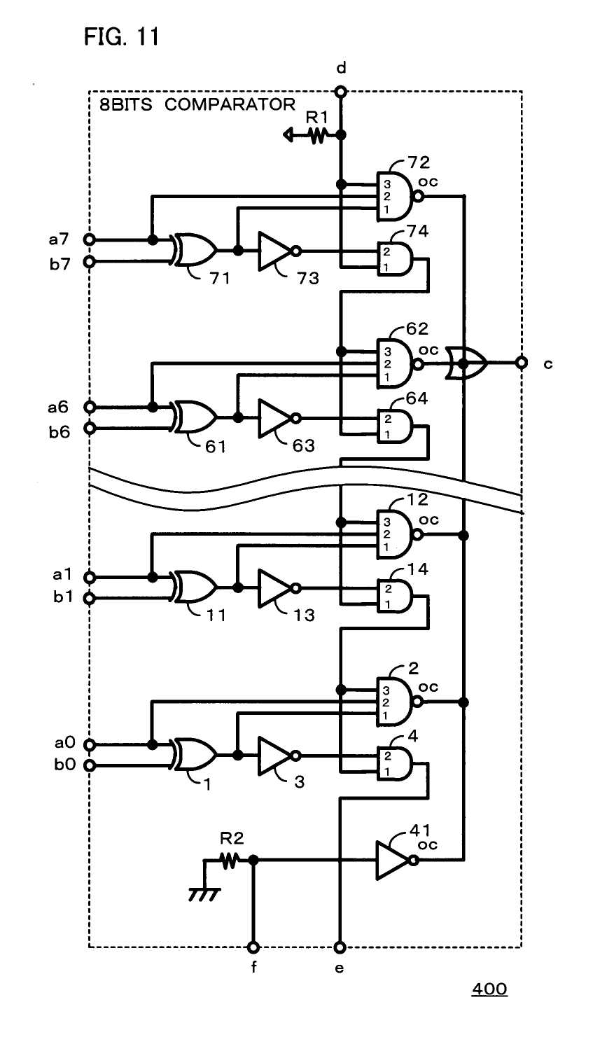

Next, a data processing circuit of a third embodiment will be described in detail below, with reference to FIGS. 9 and 11.

FIG. 9 is a circuit diagram showing a 4 bits comparator 300 of a third embodiment in accordance with the present invention. The comparator 300 includes four XOR (exclusive OR) gates 1, 11, 21, and 31; four 3NAND gates 2, 12, 22 and 32, each of which have three input (1) to (3); five inverters 3, 13, 23, 33, and 41; four NAND gates 4, 14, 24, and 34, each of which have two inputs (1) and (2); a pull-up resistor R1 and a pull-down resistor R2; eight input terminals a0, a1, a2, and a3 and b0, b1, b2, and b3, an output terminal c, a control terminal d that is high-level through R1, a control terminal e, and a control terminal f that is low-level through R2 and connected to the input of the inverter 41.

In FIG. 9, the XOR gates 1, 11, 21, and 31 are receive 4 bits data A consisting of a0, a1, a2, and a3 and 4 bits data B consisting of b0, b1, b2, and b3. Each of a3 and b3 is the most significant bit (MSB); while each of a0 and b0 is the least significant bit (LSB). Each output of the XOR gates 1, 11, 21, and 31 are connected to each input (1) of the 3NAND gates 2, 12, 22, and 32 respectively. Each of a0, a1, a2, and a3 are also provided to each input (2) of the 3NAND gates 2, 12, 22, and 32 respectively. Each inverter gates 3, 13, 23, and 43 invert signals output from the XOR gates 1, 11, 21, and 31 and output them to each input (2) of the AND gates 4, 14, 24, and 34 respectively. The terminal d with high-level is connected to the input (3) of the 3NAND gate 32 and the input (1) of the AND gate 34. The output of the AND gate 34 is connected to the input (3) of the 3NAND gate 22 and the input (1) of the AND gate 24. The output of the AND gate 24 is connected to the input (3) of the 3NAND gate 12 and the input (1) of the AND gate 14. The output of the AND gate 14 is connected to the input (3) of the 3NAND gate 2 and the input (1) of the AND gate 4. The output of the AND gate 4 is connected to the terminal e.

Each output of the 3NAND gates 2, 12, 22, and 32 are the open collector, which are connected to the output terminal c. The output of the inverter 41 also is the open collector, which is connected to the output terminal c. That is, the outputs of the 3NAND gates 2, 12, 22, and 32 and the output of the inverter 41 compose a wired-OR gate having active low through a pull-up resistor (not shown) connected to the output terminal c. Therefore, when at least one of the outputs of the 3NAND gates 2, 12, 22, and 32 and the inverter 41 becomes low-level, the current flows into the low-level output via the pull-up resistor. However, since the input of the inverter 41 is connected to the terminal f with low-level through R2, its output is always high-level unless low-level signal is input to the terminal f.

The terminal d can be connected to an upper 4 bits comparator cascaded (not shown). The terminal e can be connected to a lower 4 bits comparator cascaded (not shown). As shown in FIG. 9, when an upper 4 bits comparator is not cascaded, the input (3) of the 3NAND gate 32 and the input (1) of the AND gate 34 are high-level through the pull-up resistor R1.

The operation of the 4 bits comparator 300 in FIG. 9 will be described in detail bellow, in accordance with the state of each bit of the data A (signals a0, a1, a2, and a3) and data B (signals b0, b1, b2, and b3).

When the signal a3 is high-level and the signal b3 is low-level, then the XOR gate 31 provides the high-level signal (i.e., mismatch signal) to the input (1) of the 3NAND gate 32. Now, the input (3) of the 3NAND gate 32 is high-level, so that the 3NAND gate 32 that acts as an inverter inverts the signal a3 and outputs the low-level signal of “negative logic”. Further, the inverter gate 33, inverting the high-level signal output from the XOR 31, provides the low-level signal to the input (2) of the AND gate 34, in turn, the AND gate 34 provides the low-level signal to the input (3) of the 3NAND gate 22 and the input (1) of the AND gate 24. Thereby, the AND gate 24 provides the low-level signal to the input (3) of the 3NAND gate 12 and the input (1) of the AND gate 14. Thereby, the AND gate 14 provides the low-level signal to the input (3) of the 3NAND gate 2 and the input (1) of the AND gate 4. Thereby, the AND gate 4 provides the low-level signal to the terminal e. As a result of this, the outputs of the 3NAND gates 2, 12, and 22 become high-level regardless of whether the outputs of the XOR 2, 12, and 22 are high-level or low-level. That is, the low-level signal of “negative logic” is output from the terminal c, only depending to output of the XOR 32. This low-level signal of “negative logic” from the terminal c is for the reason that a3 is greater than b3. Therefore, the data A is greater than the data B (A>B), regardless of other lower bits, i.e., each comparison results between a0 and b0, a1 and b1, and a2 and b2.

When the signal a3 is low-level and the signal b3 is high-level, then the XOR gate 31 provides the high-level signal to the input (1) of the 3NAND gate 32. Now, the input (3) of the 3NAND gate 32 is high-level, so that the 3NAND gate 32 that acts as an inverter inverts the signal a3 and outputs the high-level signal. Further, the inverter gate 33, inverting the high-level signal output from the XOR 31, provides the low-level signal to the input (2) of the AND gate 34, in turn, the AND gate 34 provides the low-level signal to the input (3) of the 3NAND gate 22 and the input (1) of the AND gate 24. Thereby, the 3NAND gate 22 outputs the high-level signal, and the AND gate 24 provides the low-level signal to the input (3) of the 3NAND gate 12 and the input (1) of the AND gate 14. Thereby, the 3NAND gate 12 outputs the high-level signal, and the AND gate 14 provides the low-level signal to the input (3) of the 3NAND gate 2 and the input (1) of the AND gate 4. Thereby, the 3NAND gate 2 outputs the high-level signal, and the AND gate 4 provides the low-level signal to the terminal e. As a result of this, the outputs of the 3NAND gates 2, 12, and 22 become high-level regardless of whether the outputs of the XOR 2, 12, and 22 are high-level or low-level. That is, all outputs of four 3NAND gates 2, 12, 22, and 32 become high-level, so that the high-level signal is output from the terminal c. This high-level signal from the terminal c is for the reason that a3 is smaller than b3. Therefore, the data A is smaller than the data B (A<B), regardless of other lower bits, i.e., each comparison results between a0 and b0, a1 and b1, and a2 and b2.

When the signals a3 and b3 are the same level, then the XOR gate 31 provides the low-level signal (i.e., matching signal) to the input (1) of the 3NAND gate 32. Then, the 3NAND gate 32 outputs the high-level signal. Further, the inverter gate 33, inverting the low-level signal output from the XOR gate 32, provides high-level signal to the input (2) of the AND gate 34. Now, the input (1) of the AND gate 34 is high-level, so that the AND gate 34 provides the high-level signal to the input (3) of the 3NAND gate 22 and the input (1) of the AND gate 24.

In this case, when the signal a2 is high-level and the signal b2 is low-level, then the XOR gate 21 provides the high-level signal (i.e., mismatch signal) to the input (1) of the 3NAND gate 22. Now, the input (3) of the 3NAND gate 22 is high-level, so that the 3NAND gate 22 that acts as an inverter inverts the signal a2 and outputs the low-level signal of “negative logic”. Further, the inverter gate 23, inverting the high-level signal output from the XOR 21, provides the low-level signal to the input (2) of the AND gate 24, in turn, the AND gate 24 provides the low-level signal to the input (3) of the 3NAND gate 12 and the input (1) of the AND gate 14. Thereby, the AND gate 14 provides the low-level signal to the input (3) of the 3NAND gate 2 and the input (1) of the AND gate 4. Thereby, the AND gate 4 provides the low-level signal to the terminal e. As a result of this, the outputs of the 3NAND gates 2 and 12 become high-level regardless of whether the outputs of the XOR 2 and 12 are high-level or low-level. That is, the low-level signal of “negative logic” is output from the terminal c, only depending to output of the XOR 22. This low-level signal of “negative logic” from the terminal c is for the reason that a3 and b3 are the same level and a2 is greater than b2. Therefore, the data A is greater than the data B (A>B), regardless of other lower bits, i.e., each comparison results between a0 and b0, and a1 and b1.

When the signals a3 and b3 are the same level and the signal a2 is low-level and the signal b2 is high-level, then the XOR gate 21 provides the high-level signal (i.e., mismatch signal) to the input (1) of the 3NAND gate 22. Now, the input (3) of the 3NAND gate 22 is high-level, so that the 3NAND gate 22 that acts as an inverter inverts the signal a2 and outputs the high-level signal. Further, the inverter gate 23, inverting the high-level signal output from the XOR 21, provides the low-level signal to the input (2) of the AND gate 24, in turn, the AND gate 24 provides the low-level signal to the input (3) of the 3NAND gate 12 and the input (1) of the AND gate 14. Thereby, the 3NAND gate 12 outputs the high-level signal, and the AND gate 14 provides the low-level signal to the input (3) of the 3NAND gate 2 and the input (1) of the AND gate 4. Thereby, the 3NAND gate 2 outputs the high-level signal, and the AND gate 4 provides the low-level signal to the terminal e. As a result of this, the outputs of the 3NAND gates 2 and 12 become high-level regardless of whether the outputs of the XOR 2 and 12 are high-level or low-level. That is, all outputs of four 3NAND gates 2, 12, 22, and 32 become high-level, so that the high-level signal is output from the terminal c. This high-level signal from the terminal c is for the reason that a3 and b3 are the same level and a2 is smaller than b2. Therefore, the data A is smaller than the data B (A<B), regardless of other lower bits, i.e., each comparison results between a0 and b0, and a1 and b1.

When the signals a3 and b3 are the same level, the signals a2 and b2 are the same level, and the signal a1 is high-level and the signal b1 is low-level, then the XOR gates 31 and 21 provide the low-level signals (i.e., matching signals) to the corresponding input (1) of the 3NAND gates 32 and 22 respectively. Then, two 3NAND gates 32 and 22 output the high-level signal respectively. Further, the inverter gate 33, inverting the low-level signal output from the XOR gate 32, provides high-level signal to the input (2) of the AND gate 34. Now, the input (1) of the AND gate 34 is high-level, so that the AND gate 34 provides the high-level signal to the input (3) of the 3NAND gate 22 and the input (1) of the AND gate 24. Further, the inverter gate 23, inverting the low-level signal output from the XOR gate 22, provides high-level signal to the input (2) of the AND gate 24. Now, the input (1) of the AND gate 24 is high-level, so that the AND gate 24 provides the high-level signal to the input (3) of the 3NAND gate 12 and the input (1) of the AND gate 14.

In this case, when the signal a1 is high-level and the signal b1 is low-level, then the XOR gate 11 provides the high-level signal (i.e., mismatch signal) to the input (1) of the 3NAND gate 12. Now, the input (3) of the 3NAND gate 12 is high-level, so that the 3NAND gate 12 that acts as an inverter inverts the signal a1 and outputs the low-level signal of “negative logic”. Further, the inverter gate 13, inverting the high-level signal output from the XOR 11, provides the low-level signal to the input (2) of the AND gate 14, in turn, the AND gate 14 provides the low-level signal to the input (3) of the 3NAND gate 2 and the input (1) of the AND gate 4. Thereby, the AND gate 4 provides the low-level signal to the terminal e. As a result of this, the output of the 3NAND gate 2 becomes high-level regardless of whether the output of the XOR 2 is high-level or low-level. That is, the low-level signal of “negative logic” is output from the terminal c, only depending to output of the XOR 12. This low-level signal of “negative logic” from the terminal c is for the reason that a3 and b3 are the same level, a2 and b2 are the same level and a1 is greater than b1. Therefore, the data A is greater than the data B (A>B), regardless of other lower bits, i.e., comparison result between a0 and b0.

When the signals a3 and b3 are the same level, the signals a2 and b2 are the same level, and the signal a1 is low-level and the signal b1 is high-level, then the XOR gate 11 provides the high-level signal (i.e., mismatch signal) to the input (1) of the 3NAND gate 12. Now, the input (3) of the 3NAND gate 12 is high-level, so that the 3NAND gate 12 that acts as an inverter inverts the signal a1 and outputs the high-level signal. Further, the inverter gate 13, inverting the high-level signal output from the XOR 11, provides the low-level signal to the input (2) of the AND gate 14, in turn, the AND gate 14 provides the low-level signal to the input (3) of the 3NAND gate 2 and the input (1) of the AND gate 4. Thereby, the 3NAND gate 2 outputs the high-level signal, and the AND gate 4 provides the low-level signal to the terminal e. As a result of this, the output of the 3NAND gate 2 becomes high-level regardless of whether the output of the XOR 2 is high-level or low-level. That is, all outputs of four 3NAND gates 2, 12, 22, and 32 become high-level, so that the high-level signal is output from the terminal c. This high-level signal from the terminal c is for the reason that a3 and b3 are the same level, a2 and b2 are the same level, and a1 is smaller than b1. Therefore, the data A is smaller than the data B (A<B), regardless of other lower bits, i.e., comparison result between a0 and b0.

When the signals a3 and b3 are the same level, the signals a2 and b2 are the same level, and the signals a1 and b1 are the same level, then the XOR gates 31 to 11 provide the low-level signals (i.e., matching signals) to the corresponding input (1) of the 3NAND gate 32 to 12 respectively. Then, three 3NAND gates 32 to 12 output the high-level signal respectively. Further, the inverter gate 33, inverting the low-level signal output from the XOR gate 32, provides high-level signal to the input (2) of the AND gate 34. Now, the input (1) of the AND gate 34 is high-level, so that the AND gate 34 provides the high-level signal to the input (3) of the 3NAND gate 22 and the input (1) of the AND gate 24. Further, the inverter gate 23, inverting the low-level signal output from the XOR gate 22, provides high-level signal to the input (2) of the AND gate 24. Now, the input (1) of the AND gate 24 is high-level, so that the AND gate 24 provides the high-level signal to the input (3) of the 3NAND gate 12 and the input (1) of the AND gate 14. Further, the inverter gate 13, inverting the low-level signal output from the XOR gate 12, provides high-level signal to the input (2) of the AND gate 14. Now, the input (1) of the AND gate 14 is high-level, so that the AND gate 14 provides the high-level signal to the input (3) of the 3NAND gate 2 and the input (1) of the AND gate 4.

In this case, when the signal a0 is high-level and the signal b0 is low-level, then the XOR gate 1 provides the high-level signal (i.e., mismatch signal) to the input (1) of the 3NAND gate 2. Now, the input (3) of the 3NAND gate 2 is high-level, so that the 3NAND gate 2 that acts as an inverter inverts the signal a0 and outputs the low-level signal of “negative logic”. Further, the inverter gate 3, inverting the high-level signal output from the XOR 1, provides the low-level signal to the input (2) of the AND gate 4, in turn, the AND gate 4 provides the low-level signal to the terminal e. As a result of this, the low-level signal of “negative logic” is output from the terminal c, only depending to output of the XOR 2. This low-level signal of “negative logic” from the terminal c is for the reason that a3 and b3 are the same level, a2 and b2 are the same level, a1 and b1 are the same level, and a0 is greater than b0. Therefore, the data A is greater than the data B (A>B).

When the signals a3 and b3 are the same level, the signals a2 and b2 are the same level, the signals a1 and b1 are the same level, and the signal a0 is low-level and the signal b0 is high-level, then the XOR gate 1 provides the high-level signal (i.e., mismatch signal) to the input (1) of the 3NAND gate 2. Now, the input (3) of the 3NAND gate 2 is high-level, so that the 3NAND gate 2 that acts as an inverter inverts the signal a0 and outputs the high-level signal. Further, the inverter gate 3, inverting the high-level signal output from the XOR 1, provides the low-level signal to the input (2) of the AND gate 4, in turn, the AND gate 4 provides the low-level signal to the terminal e. As a result of this, all outputs of four 3NAND gates 2, 12, 22, and 32 become high-level, so that the high-level signal is output from the terminal c. This high-level signal from the terminal c is for the reason that a3 and b3 are the same level, a2 and b2 are the same level, a1 and b1 are the same level, and a0 is smaller than b0. Therefore, the data A is smaller than the data B (A<B).

When the signals a3 and b3 are the same level, the signals a2 and b2 are the same level, the signals a1 and b1 are the same level, and the signals a0 and b0 are the same level, then the XOR 1 to 31 output the low-level signals (i.e., matching signals) to the corresponding input (1) of the 3NAND gates 2 to 32 respectively. Thereby, all 3NAND gates 2 to 32 output the high-level signals. In this case, the inverter 33, inverting the low-level signal from the XOR gate 31, provides the high-level signal to the input (2) of the AND gate 34. Now, the input (1) of the AND gate 34 is high-level, so that the AND gate 34 outputs the high-level signal to the input (1) of the AND gate 24. Further, the inverter 23, inverting the low-level signal from the XOR gate 21, provides the high-level signal to the input (2) of the AND gate 24. Now, the input (1) of the AND gate 24 is high-level, so that the AND gate 24 outputs the high-level signal to the input (1) of the AND gate 14. Further, the inverter 13, inverting the low-level signal from the XOR gate 11, provides the high-level signal to the input (2) of the AND gate 14. Now, the input (1) of the AND gate 14 is high-level, so that the AND gate 14 outputs the high-level signal to the input (1) of the AND gate 4. Further, the inverter 3, inverting the low-level signal from the XOR gate 1, provides the high-level signal to the input (2) of the AND gate 4. Now, the input (1) of the AND gate 4 is high-level, so that the AND gate 4 outputs the high-level signal to the terminal e.

In this way, the 4 bits comparator 300 in FIG. 9 compares the data A with 4 bits and the data B with 4 bits, outputs the low-level signal of “negative logic” from the terminal c, when the data A is greater than the data B (A>B); while outputs the high-level signal from the terminal c, when the data A is smaller than or equal to the data B (A≦B). Further, the comparator 300 outputs the low-level signal from the terminal e, when the data A and data B are different (A>B or A<B); while outputs the high-level signal from the terminal e, when the data A and data B is the same, i.e., a3=b3, a2=b2, a1=b1, and a0=b0. That is, with the assumption that high-level is “1” and low-level is “0”, the relation between the output terminal c and the terminal e; and the data A and data B is represented as follows:

c=0 (A>B); c=1 (A≦B)

e=0 (A>B or A<B); e=1 (A=B)

Therefore, by detecting whether the terminal e is low-level “0” or high-level “1”, it is able to distinguish between (A<B) and (A=B) when c=1 (A≦B)

In addition, when connecting the terminal e and terminal f, the high-level signal or low-level signal is input to the input of the inverter 41 from the terminal e, when e=1 or 0. Therefore, the relation between the output terminal c and the terminal e; and the data A and data B is represented as follows:

c=0 (A≧B); c=1 (A<B)

e=0 (A>B or A<B); e=1 (A=B)

In this case also, by detecting whether the terminal e is low-level “0” or high-level “1”, it is able to distinguish between (A>B) and (A=B) when c=0 (A≧B).

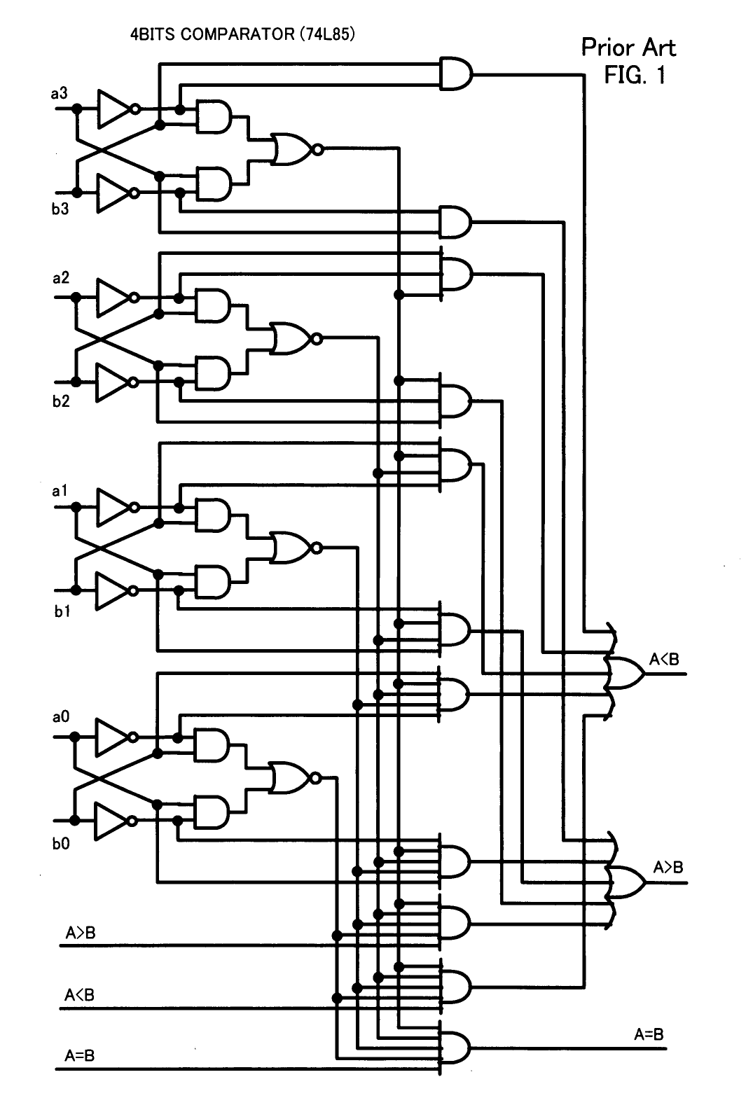

As described above, in accordance with the 4 bits comparator of the data processing circuit of the third embodiment, if it is composed of an integrate circuit, then providing significantly to reduce winding patterns more than a conventional 4 bits comparator such as TTL; 74L85 or CMOS; 4063 or 4585. The conventional 4 bits comparator, as shown in FIG. 1, is further required 3 bits input signals (A>B), (A<B) and (A=B), and 3 bits output signals (A>B), (A<B) and (A=B).

Therefore, the 4 bits comparator of the third embodiment provides data processing with high-speed by reducing delay of data that results from stray capacitances between winding patterns.

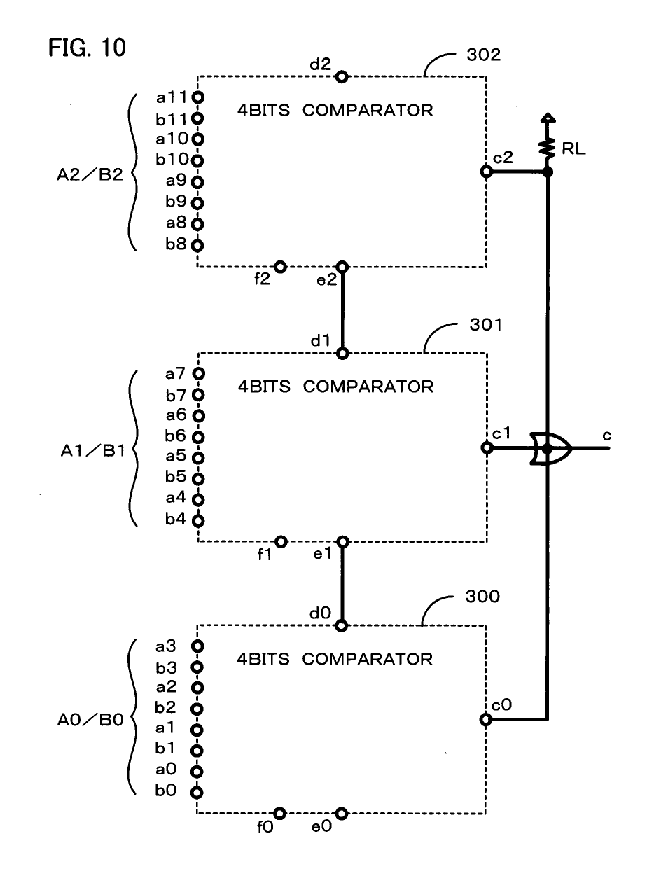

Next, the cascade connection of the 4 bits comparator in FIG. 9 will be described. FIG. 10 is a schematic block diagram of a 12 bits comparator by cascading three 4 bits comparators, i.e., an upper one 302, a middle one 301, and a lower one 300. As shown in FIG. 10, a terminal e2 of the upper comparator 302 is connected to a terminal dl of the middle comparator 301; a terminal e1 of the middle comparator 301 is connected to a terminal d0 of the lower comparator 300. Further, output terminals c2, c1, and c0 of the comparators 302, 301, and 300 are connected each other and connected to a power source (not shown) via a pull-up resistor RL. That is, the output terminals c2, c1, and c0 are wired-OR of “negative logic”. 4 bits data A2 (all, a10, a9, and a8) and 4 bits data B2 (b11, b10, b9, and b8) are input to the upper comparator 302. 4 bits data A1 (a7, a6, a5, and a4) and 4 bits data B1 (b7, b6, b5, and b4) are input to the middle comparator 301. 4 bits data A0 (a3, a2, a1, and a0) and 4 bits data B0 (b3, b2, b1, and b0) are input to the upper comparator 302.

Next, the operation of this 12 bits comparator will be described bellow. However, since the operation of each comparator 302, 301, and 300 are the same as that of the comparator 300 in FIG. 9, omitting these description.

If the value of the data A2 is greater than that of the data B2 (A2>B2), then the upper comparator 302 outputs the low-level signal of “negative logic” from the terminal c2. Further, the terminal e2 outputs the low-level signal to the terminal dl of the middle comparator 301. Thereby, the middle comparator 301 outputs the high-level signal from the terminal c1. Further, the terminal e1 outputs the low-level signal to the terminal d0 of the lower comparator 300. Thereby, the lower comparator 300 outputs the high-level signal from the terminal c0. Further the terminal e0 outputs the low-level signal.

If the value of the data A2 is smaller than that of the data B2 (A2<B2), then the upper comparator 302 outputs the high-level signal from the terminal c2. Further, the terminal e2 outputs the low-level signal to the terminal dl of the middle comparator 301. Thereby, the middle comparator 301 outputs the high-level signal from the terminal c1. Further, the terminal e1 outputs the low-level signal to the terminal d0 of the lower comparator 300. Thereby, the lower comparator 300 outputs the high-level signal from the terminal c0. Further the terminal e0 outputs the low-level signal.

If the values of the data A2 and B2 are the same level (A2=B2), then the upper comparator 302 outputs the high-level signal from the terminal c2. Further, the terminal e2 outputs the high-level signal to the terminal dl of the middle comparator 301. In this case, if the value of the data A1 is greater than that of the data B1 (A1>B1) then the middle comparator 301 outputs the low-level signal of “negative logic” from the terminal c1. Further, the terminal e1 outputs the low-level signal to the terminal d0 of the lower comparator 300. Thereby, the lower comparator 300 outputs the high-level signal from the terminal c0. Further, the terminal e0 outputs the low-level signal.

When the values of the data A2 and B2 are the same level (A2=B2), if the value of the data A1 is smaller than that of the data B1 (A1<B1), then the middle comparator 301 outputs the high-level signal from the terminal c1. Further, the terminal e1 outputs the low-level signal to the terminal d0 of the lower comparator 300. Thereby, the lower comparator 300 outputs the high-level signal from the terminal c0. Further the terminal e0 outputs the low-level signal.

When the values of the data A2 and B2 are the same level (A2=B2), and the values of the data A1 and B1 are the same level (A1=B1), then the upper and middle comparators 302 and 301 output the high-level signal from the terminal c2 and c1 respectively. Further, the terminal e2 outputs the high-level signal to the terminal dl of the middle comparator 301; the terminal e1 outputs the high-level signal to the terminal d0 of the lower comparator 300. In this case, if the value of the data A0 is greater than that of the data B0 (A0>B0), then the lower comparator 300 outputs the low-level signal of “negative logic” from the terminal c0. Further the terminal e0 outputs the low-level signal.

When the values of the data A2 and B2 are the same level (A2=B2), and the values of the data A1 and B1 are the same level (A1=B1), if the value of the data A0 is smaller than that of the data B0 (A0<B0), then the lower comparator 300 outputs the high-level signal from the terminal c0. Further the terminal e0 outputs the low-level signal.

When the values of the data A2 and B2 are the same level (A2=B2), the values of the data A1 and B1 are the same level (A1=B1), and the values of the data A0 and B0 are the same level (A0=B0), then the upper, middle, and lower comparators 302, 301, and 300 output the high-level signal from the terminal c2, c1, and c0 respectively. Further the terminal e0 outputs the high-level signal.

In this way, with cascade connection of the three 4 bits comparators, i.e., the upper one 302, middle one 301, and lower one 300, as though each 4 bits comparator operates as a 1 bit comparator; because an upper comparator and a lower comparator are cascaded by 1 bit information. The 1 bit information indicates whether the comparison data of the upper comparator is different (e=0) or equal (e=1). Therefore, by using only 1 bit information (also referred to herein as “e signal”), it is provided cascading between comparators, each of which compares two parallel data regardless of the number of those bits.

FIG. 11 is a circuit diagram showing an 8 bits comparator 400. As shown in FIG. 11, the comparator 400 receives 1 bit “e signal” from an upper comparator (not shown) via a terminal d, compares 8 bits data (a7 to a0 and b7 to b0), and outputs 1 bit “e signal” to a lower comparator (not shown) via a terminal e.

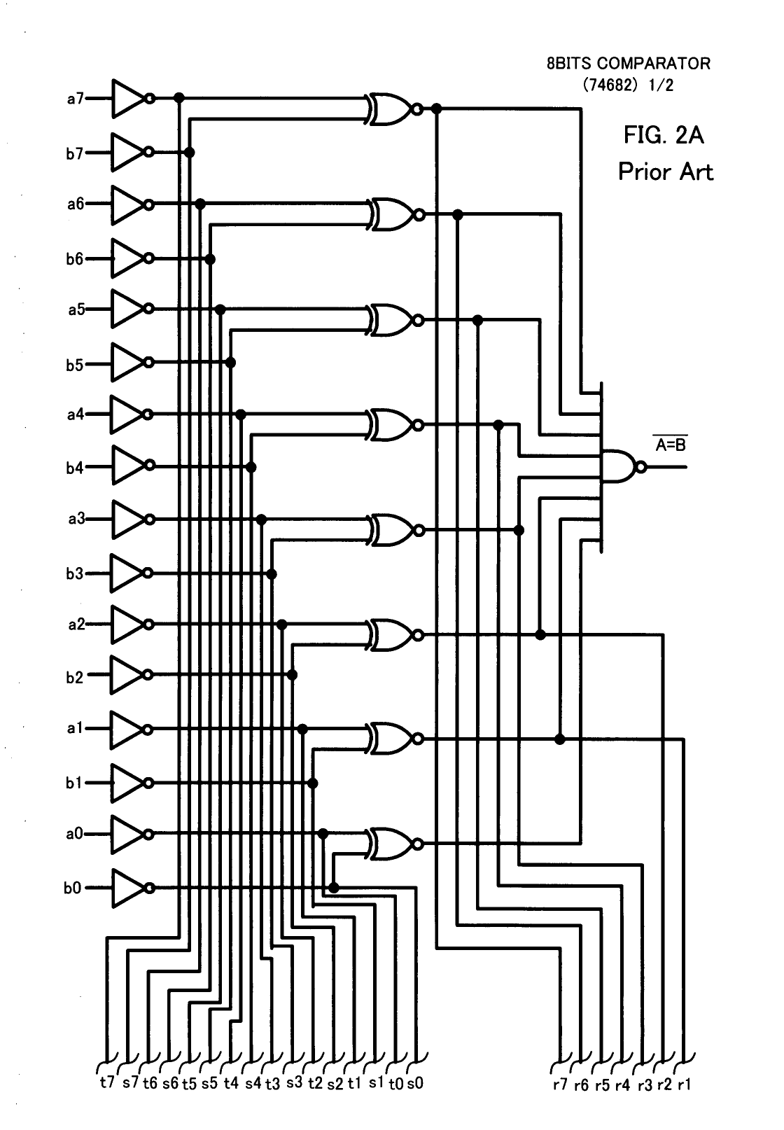

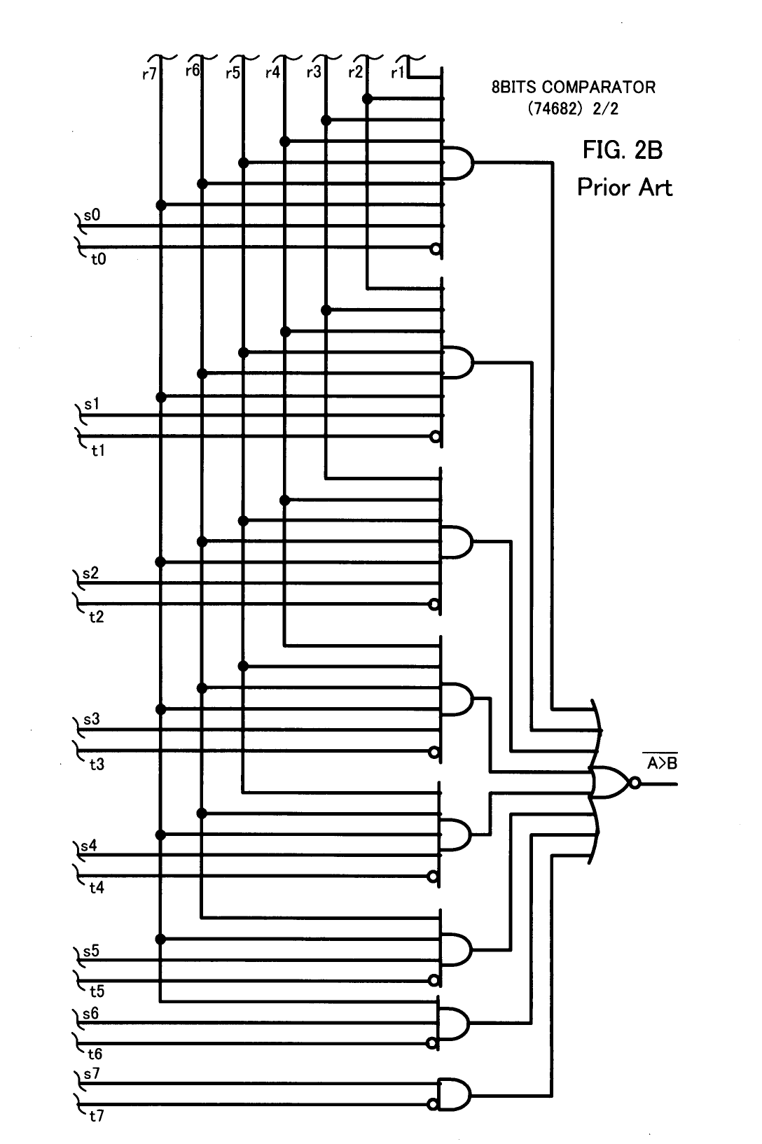

As described above, in accordance with the 8 bits comparator of the data processing circuit of the third embodiment, if it is composed of an integrate circuit, then providing significantly to reduce winding patterns more than a conventional 8 bits comparator such as TTL; 74682. The conventional 8 bits comparator, as shown in FIGS. 2A and 2B, is required many winding patterns.

Therefore, the 8 bits comparator of the third embodiment provides data processing with exceptionally high-speed by reducing delay of data that results from stray capacitances between winding patterns.

What is claimed is:

1. A digital comparator circuit for comparing a first data with a predetermined number of bits from a most significant bit to a least significant bit and a second data with the same number of bits inputting from outside, the digital comparator circuit having a plurality of bit comparators corresponding to the number of bits of the first and second data, wherein each bit comparator comprising:
an input circuit for generating a matching signal when the values between a first 1 bit data and a second 1 bit data are equal, while a mismatch signal when the values between the first 1 bit data and the second 1 bit data are unequal;
a receiving circuit for receiving a matching signal or a mismatch signal transmitted from an upper bit comparator or a fixed signal generated by a predetermined electronics component;
a transmitting circuit for transmitting a mismatch signal to a lower bit comparator when the input circuit generates the mismatch signal or the receiving circuit receives the mismatch signal, while a matching signal to the lower bit comparator when the input circuit generates the matching signal and the receiving circuit receives the matching signal or the fixed signal; and
an output circuit for outputting the first 1 bit data being input to the input circuit when the input circuit generates the mismatch signal and the receiving circuit receives the matching signal or the fixed signal.

2. A median filer circuit for processing data having 2n+1 pixel data (n is one or more integers) consisting of a sequentially specified one pixel data among a number of pixel data stored in an image memory circuit with two-dimensional style and surrounding pixel data adjacent to the specified pixel data comprising:
a data processing circuit including 2n+1 pixel storage circuits with cascade connection each storing one pixel data;
a storage control circuit, when 2n+1 pixel data are sequentially read out one by one, for comparing a value of the read out pixel data and each value of currently stored pixel data in the 2n+1 pixel storage circuits, and designating one pixel storage circuit to store the read out pixel data so as to store 2n+1 pixel data in ascending or descending order; and
a rewriting control circuit, when after the read out 2n+1 pixel data have been stored in the 2n+1 pixel storage circuits in ascending or descending order based on the designation of the storage control circuit, for replacing the specified pixel data with the pixel data stored in the nth pixel storage circuit in response to a predetermined input rewriting signal.

3. The median filer circuit according to claim 2, wherein the storage control circuit having a digital comparator circuit for comparing a first data with a predetermined number of bits from a most significant bit to a least significant bit and a second data with the same number of bits inputting from outside, the digital comparator circuit having a plurality of bit comparators corresponding to the number of bits of the first and second data, wherein each bit comparator comprising:
an input circuit for generating a matching signal when the values between a first 1 bit data and a second 1 bit data are equal, while a mismatch signal when the values between the first 1 bit data and the second 1 bit data are unequal;
a receiving circuit for receiving a matching signal or a mismatch signal transmitted from an upper bit comparator or a fixed signal generated by a predetermined electronics component;
a transmitting circuit for transmitting a mismatch signal to a lower bit comparator when the input circuit generates the mismatch signal or the receiving circuit receives the mismatch signal, while a matching signal to the lower bit comparator when the input circuit generates the matching signal and the receiving circuit receives the matching signal or the fixed signal; and
an output circuit for outputting the first 1 bit data being input to the input circuit when the input circuit generates the mismatch signal and the receiving circuit receives the matching signal or the fixed signal.

4. An integrate circuit incorporating the digital comparator circuit of claim 1 into one-chip semiconductor.

5. The integrate circuit according to claim 4, wherein the digital comparator circuit includes k units of comparator (k are two or more) cascading j bits comparator (j are one or more), the digital comparator circuit comparing a first (j times k) bits data and a second (j times k) bits data.

6. An integrate circuit incorporating the median filter circuit of claim 2 into a semiconductor.

7. An image processing apparatus for reducing noise of image data to process, wherein the apparatus includes an integrate circuit incorporating the median filter circuit of claim 6.

8. The image processing apparatus according to claim 7, further comprising a memory storing image data, wherein the median filter circuit reads out image data from the memory, reduces noise of the image data, and replace the image data read out with the image data reduced noise.
